(19) United States
(12) Patent Application Publication
(10) Pub. No.: US 2026/0059943 A1
(43) Pub. Date: Feb. 26, 2026

(54) DISPLAY PANEL, MANUFACTURING METHOD FOR THE SAME, AND ELECTRONIC DEVICE INCLUDING THE DISPLAY PANEL

(71) Applicant: Samsung Display Co., Ltd., Yongin-si (KR)

(72) Inventors: HYUNEOK SHIN, Yongin-si (KR); JOONYONG PARK, Yongin-si (KR); SUKYOUNG YANG, Yongin-si (KR); DONGMIN LEE, Yongin-si (KR)

(21) Appl. No.: 19/252,592

(22) Filed: Jun. 27, 2025

(30) Foreign Application Priority Data
Aug. 23, 2024 (KR) 10-2024-0113191

(51) Int. Cl. H10K 59/122; H10K 59/12; H10K 59/80; H10K 59/88

(52) U.S. Cl. CPC H10K 59/122; H10K 59/1201; H10K 59/873; H10K 59/88

(57) ABSTRACT

A display panel includes a base layer and a display element layer, which is disposed on the base layer and in which a light-emitting region and a non-light-emitting region adjacent to the light-emitting region are defined. The display element layer includes a pixel-defining film disposed on the base layer and defining a light-emitting opening overlapping the light-emitting region and a first opening overlapping the non-light-emitting region in a plan view, a partition wall disposed on the pixel-defining film and defining a partition wall opening overlapping the light-emitting opening and a non-light-emitting partition wall opening overlapping the first opening in the plan view, and a light-emitting element disposed in the light-emitting opening or the partition wall opening, and having an anode, a light-emitting pattern, and a cathode in contact with the partition wall.

This application claims priority to Korean Patent Application No. 10-2024-0113191, filed on Aug. 23, 2024, and all the benefits accruing therefrom under 35 U.S. C. § 119, the content of which in its entirety is herein incorporated by reference.

### BACKGROUND

The present disclosure herein relates to a display panel and a manufacturing method for the display panel, and more particularly, to a display panel with improved display quality.

A display device that provides an image to a user, such as a television, a monitor, a smartphone, and a tablet computer, includes a display panel displaying the image. Various display panels, such as a liquid crystal display panel, an organic light-emitting display panel, an electrowetting display panel, and an electrophoretic display panel are being developed as the display panel.

The organic light-emitting display panel may include an anode, a cathode, and a light-emitting pattern. The light-emitting pattern may be separated for each light-emitting region, and the cathode may provide a voltage to the light-emitting regions in common.

### SUMMARY

The present disclosure provides a display panel with improved display quality where a light-emitting element is formed without using a metal mask, and a manufacturing method for the same.

An embodiment of the invention provides a display panel including a base layer, and a display element layer which is disposed on the base layer, and in which a light-emitting region and a non-light-emitting region adjacent to the light-emitting region are defined. The display element layer includes a pixel-defining film disposed on the base layer and defining a light-emitting opening overlapping the light-emitting region and a first opening overlapping the non-light-emitting region in a plan view, a partition wall disposed on the pixel-defining film, and defining a partition wall opening overlapping the light-emitting opening and a non-light-emitting partition wall opening overlapping the first opening in the plan view, and a light-emitting element disposed in the light-emitting opening or the partition wall opening, and having an anode, a light-emitting pattern, and a cathode in contact with the partition wall.

In an embodiment, the display element layer may further include a first dummy pattern including the same material as a material of the light-emitting pattern, and a second dummy pattern including the same material as a material of the cathode.

In an embodiment, the first dummy pattern and the second dummy pattern may be disposed in the first opening or the non-light-emitting partition wall opening.

In an embodiment, the first dummy pattern and the second dummy pattern may be disposed on the partition wall between the partition wall opening and the non-light-emitting partition wall opening.

In an embodiment, the display panel may further include an inorganic lower encapsulation pattern which covers the light-emitting element and the second dummy pattern.

In an embodiment, a portion of the inorganic lower encapsulation pattern may be disposed in the partition wall opening and the non-light-emitting partition wall opening, and another portion of the inorganic lower encapsulation pattern may be disposed on the partition wall.

In an embodiment, the anode may be disposed overlapping the light-emitting region.

In an embodiment, the anode may be disposed overlapping the light-emitting region and the non-light-emitting region.

In an embodiment, the display element layer may further define a second opening in the same layer with the anode and overlapping the first opening and the non-light-emitting partition wall opening in the plan view, and the first dummy pattern may be disposed in the first opening and the second opening.

In an embodiment, the partition wall may include a first partition wall layer disposed on the pixel-defining film, and a second partition wall layer disposed on the first partition wall layer, the partition wall opening may include a first region defined by a side surface of the first partition wall layer and a second region defined by a side surface of the second partition wall layer, a width of the first region in one direction is larger than a width of the second region in the one direction, and the one direction may be parallel to a major surface of the base layer.

In an embodiment, the non-light-emitting partition wall opening may include a first region defined by a side surface of the first partition wall layer, and a second region defined by a side surface of the second partition wall layer, and a width of the first region in the one direction may be larger than a width of the second region in the one direction.

In an embodiment of the invention, a manufacturing method for a display panel includes providing a preliminary display panel including a base layer, first and second anodes disposed on the base layer, and a pixel-defining film covering the first and second anodes, forming a preliminary partition wall on the preliminary display panel, etching the preliminary partition wall to form a partition wall which defines first and second partition wall openings overlapping the first and second anodes in a plan view, and defines a non-light-emitting partition wall opening between the first and second partition wall openings, etching the pixel-defining film to form first and second light-emitting openings overlapping the first and second partition wall openings and a first opening overlapping the non-light-emitting partition wall opening in the plan view, and forming a first light-emitting pattern and a first cathode in the first light-emitting opening and the first partition wall opening.

In an embodiment, the manufacturing method may further include forming a first inorganic lower encapsulation pattern which covers a first light-emitting element.

In an embodiment, the manufacturing method may further include drying moisture which exists in the non-light-emitting partition wall opening and the first opening.

In an embodiment, the manufacturing method may further include forming a second light-emitting pattern and a second cathode in the second light-emitting opening and the second partition wall opening, and forming a first dummy pattern and a second dummy pattern in the non-light-emitting partition wall opening and the first opening, and on the first inorganic lower encapsulation pattern and the partition wall.

In an embodiment, the second light-emitting pattern may include the same material as a material of the first dummy pattern, and the second cathode may include the same material as a material of the second dummy pattern.

In an embodiment, the manufacturing method may further include forming a second inorganic lower encapsulation pattern which covers the second dummy pattern and a second light-emitting element.

In an embodiment, the second anode may be disposed overlapping the non-light-emitting partition wall opening and the second partition wall opening in the plan view.

In an embodiment, the manufacturing method may further include etching the second anode, which overlaps the non-light-emitting partition wall opening, to form a second opening overlapping the first opening in the plan view.

In an embodiment, the partition wall, which defines the first and second partition wall openings and the non-light-emitting partition wall opening, may include a first partition wall layer and a second partition wall layer, each of the first and second partition wall openings and the non-light-emitting partition wall opening may include a first region defined by a side surface of the first partition wall layer and a second region defined by a side surface of the second partition wall layer, a width of the first region in one direction may be larger than a width of the second region in the one direction, and the one direction may be parallel to a major surface of the base layer.

In an embodiment of the invention, an electronic device includes a display panel, and the display panel including a base layer and a display element layer which is disposed on the base layer, and in which a light-emitting region and a non-light-emitting region adjacent to the light-emitting region are defined, wherein the display element layer includes a pixel-defining film disposed on the base layer, and defining a light-emitting opening overlapping the light-emitting region and a first opening overlapping the non-light-emitting region, a partition wall disposed on the pixel-defining film in a plan view, and defining a partition wall opening overlapping the light-emitting opening and a non-light-emitting partition wall opening overlapping the first opening in the plan view, and a light-emitting element disposed in the light-emitting opening or the partition wall opening, and having an anode, a light-emitting pattern, and a cathode in contact with the partition wall.

In an embodiment, the electronic device may be a television, a monitor, a billboard, a personal computer, a laptop computer, a personal digital assistant, a car navigation unit, a game console, a smartphone, a tablet computer, or a camera.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device according to an embodiment of the invention;

FIG. 1B is an exploded perspective view of a display device according to an embodiment of the invention;

FIG. 2 is a cross-sectional view of a display module according to an embodiment of the invention;

FIG. 3 is a plan view of a display panel according to an embodiment of the invention;

FIG. 4 is an enlarged plan view partially illustrating a display region of a display panel according to an embodiment of the invention;

FIG. 5 is a cross-sectional view of a display panel taken along line I-I′ of FIG. 3;

FIG. 6 is a cross-sectional view taken along line II-II′ of FIG. 4;

FIG. 7 is a cross-sectional view taken along line II-II′ of FIG. 4 according to another embodiment;

FIGS. 8A to 8I are cross-sectional views illustrating some steps of a manufacturing method for a display panel according to an embodiment of the invention;

FIGS. 9A to 9D are cross-sectional views illustrating some steps of a manufacturing method for a display panel according to an embodiment of the invention; and

FIGS. 10A to 10C are cross-sectional views illustrating some steps of a manufacturing method for a display panel according to an embodiment of the invention.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section. In this specification, “a”, “an” and “the” are intended to include the plural forms as well, unless the context clearly indicates otherwise.

In addition, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “include” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by the persons ordinary skilled in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention will be described with reference to the accompanying drawings.

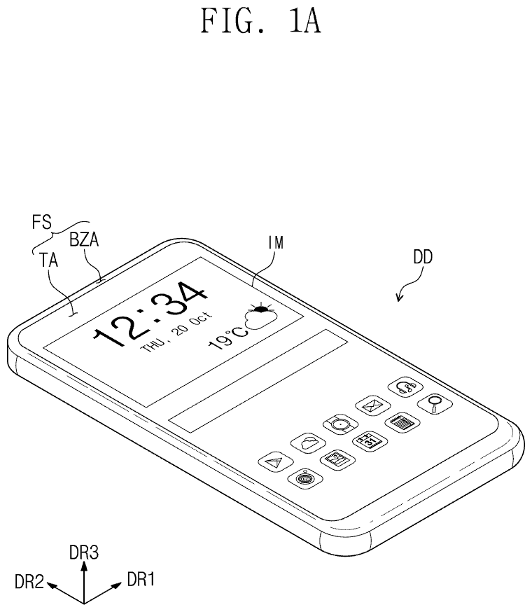

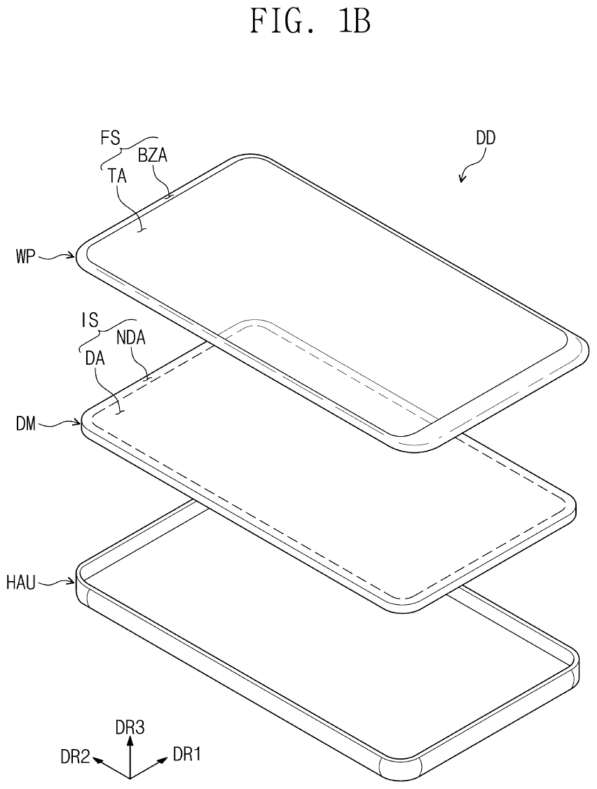

FIG. 1A is a perspective view of a display device DD according to an embodiment of the invention, and FIG. 1B is an exploded perspective view of a display device DD according to an embodiment of the invention.

In an embodiment, the display device DD may be a large-sized electronic device such as a television, a monitor, or a billboard. In addition, the display device DD may be a small- and medium-sized electronic device such as a personal computer, a laptop computer, a personal digital assistant, a car navigation unit, a game console, a smartphone, a tablet computer, and a camera. However, this is an example, and the display device may also be employed as another display device as long as it does not deviate from the scope of the invention. FIGS. 1A and 1B exemplarily illustrate the display device DD as a smartphone.

Referring to FIGS. 1A and 1B, the display device DD may display an image IM on a display surface FS, parallel to each of a first direction DR1 and a second direction DR2, toward a third direction DR3. The image IM may include a still image as well as a dynamic image. FIG. 1A illustrates a clock and icons as an example of the image IM. The display surface FS on which the image IM is displayed may correspond to a front surface of the display device DD.

In this embodiment, a front surface (or upper surface) and a rear surface (or lower surface) of each of members are defined on the basis of a direction in which the image IM is displayed. The front surface and the rear surface may be opposed to each other in the third direction DR3, and the normal direction of each of the front surface and the rear surface may be parallel to the third direction DR3. Meanwhile, directions indicated by the first to third directions DR1, DR2, and DR3 may have relative concepts, and may thus be changed to other directions. In this specification, “plan view” may mean a view in a thickness direction (i.e., the third direction DR3) of the display panel DP.

The display device DD may include a window WP, a display module DM, and a housing HAU. The window WP and the housing HAU may be coupled to each other to provide an exterior of the display device DD.

The window WP may include an optically transparent insulating material. For example, the window WP may include glass or plastic. A front surface of the window WP may define the display surface FS of the display device DD. The display surface FS may include a transmission region TA and a bezel region BZA. The transmission region TA may be an optically transparent region. For example, the transmission region TA may be a region having a visible-light transmittance of about 90% or greater.

The bezel region BZA may be a region which is relatively low in light transmittance, compared to the transmission region TA. The bezel region BZA may define a shape of the transmission region TA. The bezel region BZA may be adjacent to the transmission region TA to surround the transmission region TA. However, this is exemplarily illustrated, and the bezel region BZA of the window WP may be omitted. The window WP may include at least any one functional layer among an anti-fingerprint layer, a hard-coating layer, and an anti-reflection layer, and is not limited to any one embodiment of the invention.

The display module DM may be disposed under the window WP. The display module DM may be a component that substantially generates the image IM. The image IM generated in the display module DM is displayed on a display surface IS of the display module DM, and is viewed to a user in the outside through the transmission region TA.

The display module DM may include a display region DA and a non-display region NDA. The display region DA may be a region activated in response to electrical signals. The non-display region NDA may be adjacent to the display region DA. The non-display region NDA may surround the display region DA. The non-display region NDA may be a region covered by the bezel region BZA, and may not be visible from the outside.

The housing HAU may be coupled to the window WP. The housing HAU may be coupled to the window WP to provide a predetermined inner space. The display module DM may be accommodated in the inner space.

The housing HAU may include a material that is relatively high in rigidity. For example, the housing HAU may include glass, plastic, or metal, or may include a plurality of frames and/or plates composed of a combination thereof. The housing HAU may stably protect components of the display device DD, accommodated in the inner space, from external impact.

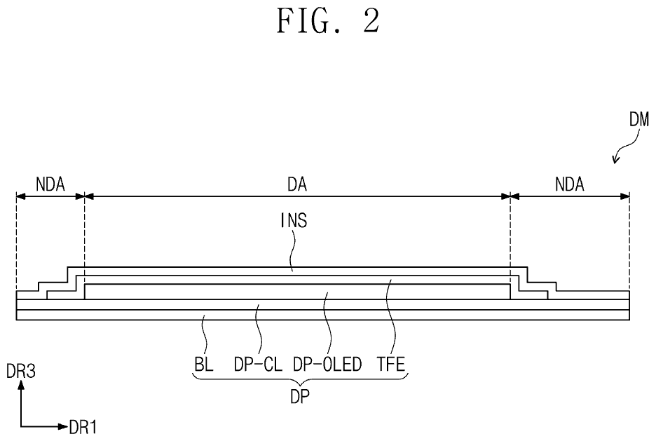

FIG. 2 is a cross-sectional view of a display module DM according to an embodiment of the invention.

Referring to FIG. 2, the display module DM may include a display panel DP and an input sensor INS. Although not separately illustrated in the drawing, the display device DD (see FIG. 1A) according to an embodiment of the invention may further include a protection member disposed on a lower surface of the display panel DP, or an anti-reflection member and/or a window member disposed on an upper surface of the input sensor INS.

The display panel DP may be an emission-type display panel. However, this is an example, and the type is not particularly limited thereto. For example, the display panel DP may be an organic light-emitting display panel or an inorganic light-emitting display panel. A light-emitting layer in the organic light-emitting display panel may include an organic light-emitting material. A light-emitting layer in the inorganic light-emitting display panel may include a quantum dot, a quantum rod, or a micro-LED. Hereinafter, the display panel DP is described as the organic light-emitting display panel.

The display panel DP may include a base layer BL, a circuit element layer DP-CL disposed on the base layer BL, a display element layer DP-OLED, and a thin-film encapsulation layer TFE. The input sensor INS may be directly disposed on the thin-film encapsulation layer TFE. In this specification, “component A directly disposed on component B” means that an adhesive layer is not disposed between the component A and component B.

The base layer BL may include at least one plastic film. The base layer BL may be a flexible substrate, which may include a plastic substrate, a glass substrate, a metal substrate, an organic/inorganic composite material substrate, or the like. The same display region DA and the non-display region NDA, described with reference to FIG. 1B, may be defined on the base layer BL.

The circuit element layer DP-CL may include at least one insulation layer and a circuit element. The insulation layer includes at least one inorganic layer and at least one organic layer. The circuit element includes signal lines, a driving circuit of a pixel, etc.

The display element layer DP-OLED may include a partition wall and a light-emitting element. The light-emitting element may include an anode, an intermediate layer, and a cathode.

The thin-film encapsulation layer TFE may include a plurality of thin films. Some thin films may be disposed in order to improve optical efficiency, and other thin films may be disposed in order to protect organic light-emitting diodes.

The input sensor INS acquires coordinate information on an external input. The input sensor INS may have a multi-layer structure. The input sensor INS may include a single-layer or multi-layer conductive layer. In addition, the input sensor INS may include a single-layer or multi-layer insulation layer. The input sensor INS may detect an external input through a capacitance manner. However, this is an example, and the input sensor INS is not limited thereto. For example, in an embodiment, the input sensor INS may also detect an external input through an electromagnetic induction or a pressure-sensing manner. Meanwhile, according to another embodiment of the invention, the input sensor INS may be omitted.

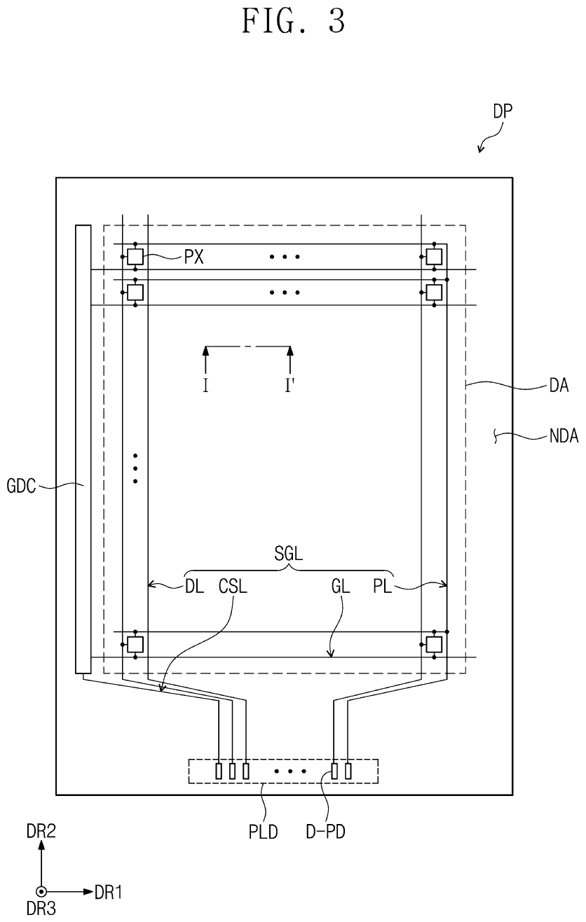

FIG. 3 is a plan view of a display panel according to an embodiment of the invention.

Referring to FIG. 3, a display region DA and a non-display region NDA around the display region DA may be defined in a display panel DP. The display panel DP may include pixels PX and signal lines SGL electrically connected to the pixels PX. The display panel DP may include a driving circuit GDC and a pad part PLD. The display region DA and the non-display region NDA may be distinguished according to whether the pixel PX is disposed or not. The pixel PX may be disposed in the display region DA. The driving circuit GDC and the pad part PLD may be disposed in the non-display region NDA.

The pixels PX may be arranged along a first direction DR1 and a second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power line PL, and a control signal line CSL. The gate lines GL may each be connected to a corresponding pixel among the pixels PX, and the data lines DL may each be connected to a corresponding pixel among the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals, and output the generated gate signals through the gate lines GL in sequence. The gate driving circuit may further output another control signal to a pixel driving circuit.

The pad part PLD may be a portion to which a flexible circuit board is connected. The pad part PLD may include pixel pads D-PD, and the pixel pads D-PD may be pads for connecting the flexible circuit board to the display panel DP. The pixel pads D-PD may each be connected to a corresponding signal line among the signal lines SGL. The pixel pads D-PD may be connected to the corresponding pixels PX through the signal lines SGL. In addition, one pixel pad, among the pixel pads D-PD, may be connected to the driving circuit GDC.

In addition, the pad part PLD may further include input pads. The input pads may be pads for connecting the flexible circuit board to the input sensor INS (see FIG. 2). However, an embodiment of the invention is not limited thereto, and the input pads may be disposed on the input sensor INS (see FIG. 2), and may thus be connected to a separate circuit board from the pixel pads D-PD. Alternatively, the input sensor INS (see FIG. 2) may be omitted, and the input pads may not be further included.

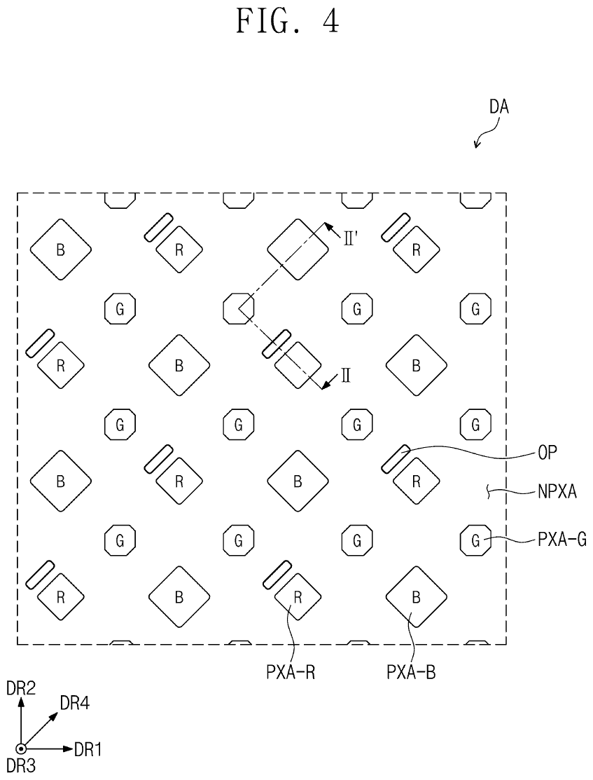

FIG. 4 is an enlarged plan view illustrating a portion of the display region DA of the display panel DP (see FIG. 2) according to an embodiment of the invention. FIG. 4 illustrates a plan view of a display module DM viewed on the display surface IS (see FIG. 1B) of the display module DM (see FIG. 1B), and illustrates the arrangement of light-emitting regions PXA-R, PXA-G, and PXA-B and an opening OP.

Referring to FIG. 4, the display region DA may include first to third light-emitting regions PXA-R, PXA-G, and PXA-B, and a non-light-emitting region NPXA surrounding the first to third light-emitting regions PXA-R, PXA-G, and PXA-B. The first to third light-emitting regions PXA-R, PXA-G, and PXA-B may correspond to regions where light provided from light-emitting elements are emitted, respectively. The first to third light-emitting regions PXA-R, PXA-G, and PXA-B may be distinguished according to a color of the light emitted toward the outside of the display module DM (see FIG. 2).

The first to third light-emitting regions PXA-R, PXA-G, and PXA-B may provide first to third color light having different colors, respectively. For example, the first color light may be red light, the second color light may be green light, and the third color light may be blue light. However, an example of the first to third color light is not necessarily limited to the above-mentioned example.

The first to third light-emitting regions PXA-R, PXA-G, and PXA-B may each be defined as a region where an upper surface of an anode is exposed by a light-emitting opening to be described later. The non-light-emitting region NPXA may set boundaries of the first to third light-emitting regions PXA-R, PXA-G, and PXA-B, and prevent color mixing between the first to third light-emitting regions PXA-R, PXA-G, and PXA-B.

The first to third light-emitting regions PXA-R, PXA-G, and PXA-B may each be provided in plurality, and may thus be repeatedly disposed with a predetermined arrangement form in the display region DA. For example, the first and third light-emitting regions PXA-R and PXA-B may be alternately arranged along a first direction DR1 to constitute a ‘first group’. The second light-emitting regions PXA-G may be arranged along the first direction DR1 to constitute a ‘second group’. The ‘first group’ and the ‘second group’ may each be provided in plurality, and the ‘first groups’ and the ‘second groups’ may be alternately arranged along a second direction DR2.

One second light-emitting region PXA-G may be disposed apart from one first light-emitting region PXA-R or one third light-emitting region PXA-B in a fourth direction DR4. The fourth direction DR4 may be defined as a direction between the first and second directions DR1 and DR2.

Meanwhile, FIG. 4 exemplarily illustrates the arrangement form of the first to third light-emitting regions PXA-R, PXA-G, and PXA-B, but the arrangement form is not limited thereto, and the first to third light-emitting regions PXA-R, PXA-G, and PXA-B may be arranged in various forms. In an embodiment, the first to third light-emitting regions PXA-R, PXA-G, and PXA-B may have a PENTILE™ arrangement form as illustrated in FIG. 4. Alternatively, the first to third light-emitting regions PXA-R, PXA-G, and PXA-B may also have a stripe arrangement form or a Diamond Pixel™ arrangement form.

The first to third light-emitting regions PXA-R, PXA-G, and PXA-B may have various shapes in a plan view. For example, the first to third light-emitting regions PXA-R, PXA-G, and PXA-B may have a polygonal, a circular, an oval shape, or the like. FIG. 4 exemplarily illustrates the first and third light-emitting regions PXA-R and PXA-B in a quadrilateral shape (or a diamond shape) and the second light-emitting region PXA-G in an octagonal shape in a plan view.

The first to third light-emitting regions PXA-R, PXA-G, and PXA-B may have the same shape, or at least some may also have different shapes in a plan view. FIG. 4 exemplarily illustrates that the first and third light-emitting regions PXA-R and PXA-B have the same shape, and the second light-emitting region PXA-G has a different shape from the first and third light-emitting regions PXA-R and PXA-B in a plan view.

At least some of the first to third light-emitting regions PXA-R, PXA-G, and PXA-B may differ from each other in area in a plan view. In an embodiment, the area of the first light-emitting region PXA-R emitting the red light may be larger than the area of the second light-emitting region PXA-G emitting the green light, and may be smaller than the area of the third light-emitting region PXA-B emitting the blue light. However, the size relationship of the areas between the first to third light-emitting regions PXA-R, PXA-G, and PXA-B, according to the color of light emitted, is not limited thereto, and may vary according to a design of the display module DM (see FIG. 2). In addition, an embodiment of the invention is not limited thereto, and the first to third light-emitting regions PXA-R, PXA-G, and PXA-B may also have the same area in a plan view.

Meanwhile, the shape, area, arrangement, etc. of the first to third light-emitting regions PXA-R, PXA-G, and PXA-B of the display module DM (see FIG. 2), according to an embodiment of the invention, may be variously designed according to the color of light to be emitted and the size and constitution of the display module DM (see FIG. 2), and are not limited to the embodiment illustrated in FIG. 4.

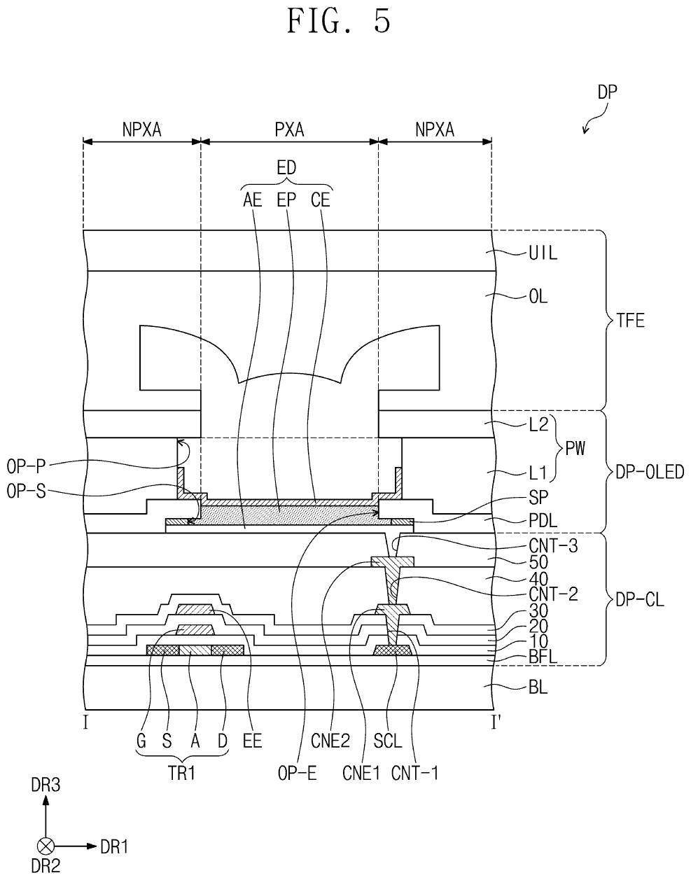

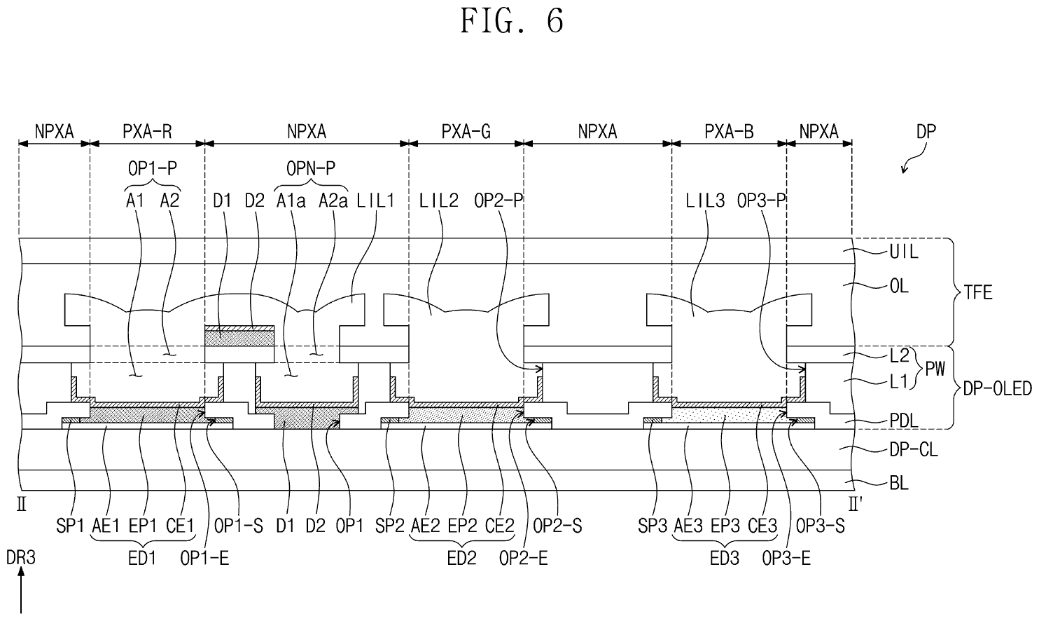

The opening OP may be defined overlapping the non-light-emitting region NPXA. For example, the opening OP may be defined overlapping the non-light-emitting region NPXA that is adjacent to the first light-emitting region PXA-R. The opening OP may correspond to a first opening OP1 in FIG. 5, or first and second openings OP1 and OP2 in FIG. 6. The opening OP may be formed adjacent to the light-emitting region PXA-R, PXA-G, or PXA-B corresponding to the last light-emitting element to be formed. FIG. 4 exemplarily illustrates that the opening OP is formed adjacent to the first light-emitting region PXA-R, but an embodiment of the invention is not limited thereto. In an embodiment, the opening OP may be defined overlapping the non-light-emitting region NPXA that is adjacent to the second light-emitting region PXA-G or the third light-emitting region PXA-B.

FIG. 5 is a cross-sectional view of the display panel taken along line I-I′ of FIG. 3. FIG. 5 is described with reference to FIG. 2, and description on the same reference symbols or numerals is omitted. FIG. 5 illustrates an enlarged view of one light-emitting region PXA in the display region DA (see FIG. 4), and the light-emitting region PXA of FIG. 5 may correspond to any one among the first to third light-emitting regions PXA-R, PXA-G, and PXA-B of FIG. 4.

Referring to FIG. 5, the display panel DP may include a base layer BL, a circuit element layer DP-CL, a display element layer DP-OLED, and a thin-film encapsulation layer TFE.

The display panel DP may include a plurality of insulation layers and a semiconductor pattern, a conductive pattern, a signal line, etc. The insulation layer, a semiconductor layer, and a conductive layer are formed through coating, deposition, etc. Thereafter, the insulation layer, the semiconductor layer, and the conductive layer may be selectively patterned by photolithography and etching. In such manner, the semiconductor pattern, the conductive pattern, the signal line, etc., included in the circuit element layer DP-CL and the display element layer DP-OLED, may be formed.

The circuit element layer DP-CL may be disposed on the base layer BL. The circuit element layer DP-CL may include a buffer layer BFL, a transistor TR1, a signal transmission region SCL, first to fifth insulation layers 10, 20, 30, 40, and 50, an electrode EE, and a plurality of connection electrodes CNE1 and CNE2.

The buffer layer BFL may be disposed on the base layer BL. The buffer layer BFL may improve bonding force between the base layer BL and the semiconductor pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon. However, an embodiment of the invention is not limited thereto, and the semiconductor pattern may also include amorphous silicon or a metal oxide. FIG. 5 illustrates a partial semiconductor pattern only as an example, and the semiconductor pattern may be further disposed in the plurality of light-emitting regions PXA-R, PXA-G, and PXA-B (see FIG. 4). The semiconductor pattern may be arranged in a certain rule across the plurality of light-emitting regions PXA-R, PXA-G, and PXA-B. The semiconductor pattern may vary in electrical property according to whether it is doped or not. The semiconductor pattern may include a first region with high doping concentration, and a second region with low doping concentration. The first region may be doped with an N-type dopant or a P-type dopant. A P-type transistor may include the first region doped with a P-type dopant.

The first region may have a conductivity higher than a conductivity of the second region, and may substantially serve as an electrode or a signal line. The second region may substantially correspond to an active (or channel) of a transistor. In other words, a portion of the semiconductor pattern may be an active of the transistor, and another portion may be a source or a drain of the transistor, and another portion may be a conductive region.

The source S, the active A, and the drain D of the transistor TR1 may be formed from the semiconductor pattern. FIG. 5 illustrates a portion of the signal transmission region SCL formed from the semiconductor pattern. Although not illustrated separately in the drawing, the signal transmission region SCL may be connected to the drain D of the transistor TR1 in a plan view.

The first to fifth insulation layers 10, 20, 30, 40, and 50 may be disposed on the buffer layer BFL. The first to fifth insulation layers 10, 20, 30, 40, and 50 may each be an inorganic layer or an organic layer.

The first insulation layer 10 may be disposed on the buffer layer BFL. The first insulation layer 10 may cover the source S, the active A, and the drain D of the transistor TR1 and the signal transmission region SCL which are disposed on the buffer layer BFL. A gate G of the transistor TR1 may be disposed on the first insulation layer 10. The second insulation layer 20 may be disposed on the first insulation layer 10 to cover the gate G. The electrode EE may be disposed on the second insulation layer 20. The third insulation layer 30 may be disposed on the second insulation layer 20 and cover the electrode EE.

The first connection electrode CNE1 may be disposed on the third insulation layer 30. The first connection electrode CNE1 may be connected to the signal transmission region SCL through a contact hole CNT-1 passing through the first to third insulation layers 10, 20, and 30. The fourth insulation layer 40 may be disposed on the third insulation layer 30 and cover the first connection electrode CNE1. The fourth insulation layer 40 may be an organic layer.

The second connection electrode CNE2 may be disposed on the fourth insulation layer 40. The second connection electrode CNE2 may be connected to the first connection electrode CNE1 through a contact hole CNT-2 passing through the fourth insulation layer 40. The fifth insulation layer 50 may be disposed on the fourth insulation layer 40 and cover the second connection electrode CNE2. The fifth insulation layer 50 may be an organic layer.

The display element layer DP-OLED may be disposed on the circuit element layer DP-CL. The display element layer DP-OLED may include a light-emitting element ED, a sacrificial pattern SP, a pixel-defining film PDL, and a partition wall PW.

The light-emitting element ED may include an anode AE (or first electrode), a light-emitting pattern EP, and a cathode CE (or second electrode). The light-emitting element ED may be disposed in a light-emitting opening OP-E and a partition wall opening OP-P, to be described later.

The anode AE may be disposed on the fifth insulation layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 defined by passing through the fifth insulation layer 50. Accordingly, the anode AE may be electrically connected to the signal transmission region SCL through the first and second connection electrodes CNE1 and CNE2, and may thus be electrically connected to a corresponding circuit element. The anode AE may have a single-layer or multi-layer structure. The anode AE may include a plurality of layers containing ITO and Ag. For example, the anode AE may include a layer containing ITO (hereinafter, lower ITO layer), a layer containing Ag (hereinafter, Ag layer) disposed on the lower ITO layer, and a layer containing ITO (hereinafter, upper ITO layer) disposed on the Ag layer.

The sacrificial pattern SP may be disposed between the anode AE and the pixel-defining film PDL. A sacrificial opening OP-S exposing a portion of an upper surface of the anode AE may be defined (or included) in the sacrificial pattern SP. The sacrificial opening OP-S may overlap the light-emitting opening OP-E to be described later.

The pixel-defining film PDL may be disposed on the fifth insulation layer 50 of the circuit element layer DP-CL. The light-emitting opening OP-E may be defined (or included) in the pixel-defining film PDL. The light-emitting opening OP-E may correspond to the anode AE, and the pixel-defining film PDL may expose at least a portion of the anode AE through the light-emitting opening OP-E.

In addition, the light-emitting opening OP-E may correspond to the sacrificial opening OP-S of the sacrificial pattern SP. According to this embodiment, the upper surface of the anode AE may be spaced apart from the pixel-defining film PDL with the sacrificial pattern SP therebetween in cross section, and accordingly, the anode AE may be protected from damage that may occur during a formation process of the light-emitting opening OP-E.

In a plan view, the area of the light-emitting opening OP-E may be smaller than the area of the sacrificial opening OP-S. That is, an inner-side surface of the pixel-defining film PDL defining the light-emitting opening OP-E may be closer to the center of the anode AE than an inner-side surface of the sacrificial pattern SP defining the sacrificial opening OP-S. However, an embodiment of the invention is not limited thereto, and the inner-side surface of the sacrificial pattern SP defining the sacrificial opening OP-S may be substantially aligned with the inner-side surface of the pixel-defining film PDL defining the light-emitting opening OP-E. At this time, the light-emitting region PXA may also be a region of the anode AE exposed from the corresponding sacrificial opening OP-S.

The pixel-defining film PDL may include an inorganic insulating material. For example, the pixel-defining film PDL may include silicon nitride (SiNₓ). The pixel-defining film PDL may be disposed between the anode AE and the partition wall PW, and may thus prevent the anode AE and the partition wall PW from being electrically connected to each other.

The light-emitting pattern EP may be disposed on the anode AE. The light-emitting pattern EP may include a light-emitting layer containing a light-emitting material. The light-emitting pattern EP may further include a hole injection layer HIL and a hole transport layer HTL disposed between the anode AE and the light-emitting layer, and also, may further include an electron transport layer ETL and an electron injection layer EIL disposed on the light-emitting layer. The light-emitting pattern EP may also be referred to as an ‘organic layer’ or an ‘intermediate layer’.

The light-emitting pattern EP may be patterned by a tip portion defined on the partition wall PW. Detailed content will be described later in description on a manufacturing method for a display panel. The light-emitting pattern EP may be disposed inside the sacrificial opening OP-S and the light-emitting opening OP-E. However, this is exemplarily illustrated, and the light-emitting pattern EP may be disposed inside at least one opening of the sacrificial opening OP-S, the light-emitting opening OP-E, or the partition wall opening OP-P. The light-emitting pattern EP may cover a portion of an upper surface of the pixel-defining film PDL.

The cathode CE may be disposed on the light-emitting pattern EP. The cathode CE may be patterned by a tip portion defined on the partition wall PW. At least a portion of the cathode CE may be disposed in the partition wall opening OP-P. FIG. 5 exemplarily illustrates that the cathode CE is disposed in the light-emitting opening OP-E and the partition wall opening OP-P, but an embodiment of the invention is not limited thereto. For example, the cathode CE may be disposed only in the partition wall opening OP-P.

The cathode CE may extend along a first inner-side surface of a first partition wall layer L1, and an end portion of the cathode CE may be in contact with the first partition wall layer L1. FIG. 5 exemplarily illustrates that the cathode CE is in contact with the first inner-side surface of the first partition wall layer L1 and the inner-side surface of the pixel-defining film PDL, but an embodiment of the invention is not limited thereto. For example, the cathode CE may be formed in contact with only the first inner-side surface of the first partition wall layer L1.

The cathode CE may have conductivity. The cathode CE may be formed of any material as long as it has conductivity, such as metal, a transparent conductive oxide (TCO), or a conductive polymer material. For example, the cathode CE may include silver (Ag), magnesium (Mg), lead (Pb), copper (Cu), or a compound thereof.

According to an embodiment of the invention, the display element layer DP-OLED may further include a capping pattern CP. The capping pattern CP may be disposed in the partition wall opening OP-P, and may be disposed on the cathode CE. The capping pattern CP may be patterned by a tip portion defined on the partition wall PW. In an embodiment, the capping pattern CP may be omitted.

The partition wall PW may be disposed on the pixel-defining film PDL. The partition wall opening OP-P may be defined in the partition wall PW. The partition wall opening OP-P may overlap the light-emitting opening OP-E in a plan view, and may expose at least a portion of the anode AE.

The partition wall PW may include multiple layers stacked in sequence. For example, the partition wall PW may include a first partition wall layer L1 and a second partition wall layer L2. The first partition wall layer L1 may be disposed on the pixel-defining film PDL, and the second partition wall layer L2 may be disposed on the first partition wall layer L1. As illustrated in FIG. 5, the thickness of the first partition wall layer L1 may be larger than the thickness of the second partition wall layer L2, but an embodiment of the invention is not limited thereto.

The first partition wall layer L1 and the second partition wall layer L2 may each include a conductive material. For example, the conductive material may include metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The partition wall PW may have an undercut shape in cross section. At least one layer among the multiple layers of the partition wall PW may be recessed compared to the other layers, and accordingly, the partition wall PW may include a tip portion. For example, the first partition wall layer L1 may have an undercut shape with respect to the second partition wall layer L2. The second partition wall layer L2 may protrude toward the light-emitting opening OP-E more than the first partition wall layer L1, so that the tip portion may be formed. A portion protruding toward the light-emitting region PXA from the first partition wall layer L1 may be defined as the tip portion in the partition wall PW. That is, a second inner-side surface of the second partition wall layer L2 may be closer to the center of the anode AE than the first inner-side surface of the first partition wall layer L1.

FIG. 5 exemplarily illustrates that the first inner-side surface of the first partition wall layer L1 and the second inner-side surface of the second partition wall layer L2 may each be perpendicular to the upper surface of the pixel-defining film PDL, but an embodiment of the invention is not limited thereto. For example, the partition wall PW may have a tapered shape, or may also have a reversed-tapered shape.

The partition wall PW may receive a driving voltage, and accordingly, the cathode CE may be electrically connected to the partition wall PW to receive the driving voltage.

The thin-film encapsulation layer TFE may be disposed on the display element layer DP-OLED. The thin-film encapsulation layer TFE may include an inorganic lower encapsulation pattern LIL, an organic encapsulation film OL, and an inorganic upper encapsulation film UIL.

The inorganic lower encapsulation pattern LIL may correspond to (or overlap) the light-emitting opening OP-E in a plan view. The inorganic lower encapsulation pattern LIL may cover the light-emitting element ED. A portion of the inorganic lower encapsulation pattern LIL may be formed in the partition wall opening OP-P, another portion of the inorganic lower encapsulation pattern LIL may be formed on the partition wall PW.

The organic encapsulation film OL may be disposed on the inorganic lower encapsulation pattern LIL. The organic encapsulation film OL may cover the inorganic lower encapsulation pattern LIL, and may provide a planar upper surface. The inorganic upper encapsulation film UIL may be disposed on the organic encapsulation film OL. The inorganic lower encapsulation pattern LIL and the inorganic upper encapsulation film UIL may protect the display element layer DP-OLED from moisture/oxygen, and the organic encapsulation film OL may protect the display element layer DP-OLED from foreign substance such as dust particles.

FIG. 6 is a cross-sectional view taken along line II-II′ of FIG. 4. FIG. 6 is an enlarged view illustrating one first light-emitting region PXA-R, one second light-emitting region PXA-G, and one third light-emitting region PXA-B, and the description on the one light-emitting region PXA in FIG. 5 may be equally applied to each of the first to third light-emitting regions PXA-R, PXA-G, and PXA-B in FIG. 6. Same/similar components as those described with reference to FIG. 5 are denoted as the same/similar reference symbols or numerals, and duplicate description thereof is omitted in description with reference to FIG. 6.

Referring to FIG. 6, a display panel DP may include a base layer BL, a circuit element layer DP-CL, a display element layer DP-OLED, and a thin-film encapsulation layer TFE. The display element layer DP-OLED may include light-emitting elements ED1, ED2, and ED3, sacrificial patterns SP1, SP2, and SP3, a pixel-defining film PDL, and a partition wall PW.

The light-emitting elements ED1, ED2, and ED3 may include a first light-emitting element ED1, a second light-emitting element ED2, and a third light-emitting element ED3 which emit different colors. The first light-emitting element ED1, the second light-emitting element ED2, and the third light-emitting element ED3 may each be provided in plurality. However, for the convenience of description, each of the first to third light-emitting elements ED1, ED2, and ED3 is hereinafter expressed in a singular form.

The first light-emitting element ED1 may include a first anode AE1, a first light-emitting pattern EP1, and a first cathode CE1. The second light-emitting element ED2 may include a second anode AE2, a second light-emitting pattern EP2, and a second cathode CE2. The third light-emitting element ED3 may include a third anode AE3, a third light-emitting pattern EP3, and a third cathode CE3. The first to third anodes AE1, AE2, and AE3 may be provided in a plurality of patterns. In an embodiment, the first to third anodes AE1, AE2, and AE3 may be disposed overlapping the light-emitting regions PXA-R, PXA-G, and PXA-B in a plan view, respectively. In an embodiment, the first light-emitting pattern EP1 may provide red light, the second light-emitting pattern EP2 may provide green light, and the third light-emitting pattern EP3 may provide blue light.

First to third light-emitting openings OP1-E, OP2-E, and OP3-E may be defined in the pixel-defining film PDL. The first light-emitting opening OP1-E may expose at least a portion of the first anode AE1. The second light-emitting opening OP2-E may expose at least a portion of the second anode AE2. The third light-emitting opening OP3-E may expose at least a portion of the third anode AE3.

In this embodiment, the first light-emitting region PXA-R may be defined as a region of an upper surface of the first anode AE1 exposed by the first light-emitting opening OP1-E. The second light-emitting region PXA-G may be defined as a region of an upper surface of the second anode AE2 exposed by the second light-emitting opening OP2-E. The third light-emitting region PXA-R may be defined as a region of an upper surface of the third anode AE3 exposed by the third light-emitting opening OP3-E.

A first opening OP1, overlapping a non-light-emitting region NPXA, may further be included in the pixel-defining film PDL. The first opening OP1 may be formed adjacent to the first light-emitting region PXA-R. In an embodiment, the first light-emitting region PXA-R may be a light-emitting region corresponding to the last light-emitting element to be formed.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be disposed on the upper surfaces of the first to third anodes AE1, AE2, and AE3, respectively. First to third sacrificial openings OP1-S, OP2-S, and OP3-S overlapping the first to third light-emitting openings OP1-E, OP2-E, and OP3-E in a plan view may be defined in the first to third sacrificial patterns SP1, SP2, and SP3, respectively.

In this embodiment, first to third partition wall openings OP1-P, OP2-P, and OP3-P overlapping the first to third light-emitting openings OP1-E, OP2-E, and OP3-E in a plan view, respectively, may be defined in the partition wall PW.

In this embodiment, the first to third light-emitting patterns EP1, EP2, and EP3 and the first to third cathodes CE1, CE2, and CE3 may be physically separated, respectively, by the second partition wall layer L2 providing a tip portion, and may thus be provided in the light-emitting openings OP1-E, OP2-E, and OP3-E and the partition wall openings OP1-P, OP2-P, and OP3-P, respectively. That is, the light-emitting elements ED1, ED2, and ED3 may be disposed in the partition wall openings OP1-P, OP2-P, and OP3-P and the light-emitting openings OP1-E, OP2-E, and OP3-E, respectively. For example, the first light-emitting element ED1 may be disposed in the first partition wall opening OP1-P and the first light-emitting opening OP1-E, the second light-emitting element ED2 may be disposed in the second partition wall opening OP2-P and the second light-emitting opening OP2-E, and the third light-emitting element ED3 may be disposed in the third partition wall opening OP3-P and the third light-emitting opening OP3-E.

According to an embodiment of the invention, a plurality of first light-emitting patterns EP1 may be patterned in a pixel unit by the tip portion, defined on the partition wall PW, to be deposited. That is, the first light-emitting patterns EP1 may be formed in common using an open mask, but may be easily divided into pixel units by the partition wall PW.

Meanwhile, if the first light-emitting patterns EP1 are patterned using a fine metal mask (FMM), a supporting spacer protruding from the conductive partition wall is desirable to be provided in order to support the fine metal mask. In addition, since the fine metal mask is spaced apart by the height of the partition wall and the spacer from a base surface where the patterning is performed, there may be a limitation in achieving high resolution. Furthermore, since the fine metal mask is in contact with the spacer, foreign substance may remain on the spacer after a patterning process of the first light-emitting patterns EP1, or the spacer may be damaged due to stamping of the fine metal mask. Accordingly, a defective display panel may be provided.

According to this embodiment, by including the partition wall PW, it may be possible to physically separate the light-emitting elements ED1, ED2, and ED3 with ease. Accordingly, it may be possible to prevent leakage current, driving error, or the like between the light-emitting regions PXA-R, PXA-G, and PXA-B adjacent to each other, and possible to operate the light-emitting elements ED1, ED2, and ED3 independently of each other.

In particular, since the plurality of first light-emitting patterns EP1 are patterned without a mask which is in contact with an internal component in the display region DA (see FIG. 1B), incidence of defects may be reduced, thereby providing a display panel DP with improved process reliability. Since the patterning is possible without a separate supporting spacer protruding from the partition wall PW, the area of each of the light-emitting regions PXA-R, PXA-G, and PXA-B may be miniaturized, thereby providing a display panel DP with the high resolution easily achieved.

In addition, in manufacturing of a large-area display panel DP, since manufacture of a large-area mask is omitted, the cost of process may be reduced, and defect that may occur on the large-area mask may not affect the process, a display panel DP with improved process reliability may be provided. Description on the plurality of first light-emitting patterns EP1 may be equally applied to a plurality of second and third light-emitting patterns EP2 and EP3.

The partition wall PW may include a first partition wall layer L1 disposed on the pixel-defining film PDL, and a second partition wall layer L2 disposed on the first partition wall layer L1. The partition wall openings OP1-P, OP2-P, and OP3-P may each include a first region A1 defined by a side surface of the first partition wall layer L1 and a second region A2 defined by a side surface of the second partition wall layer L2. The width of the first region A1 in one direction (for example, the first direction DR1 (see FIG. 4) or the second direction DR2 (see FIG. 4)) may be larger than the width of the second region A2 in the one direction (for example, the first direction DR1 or the second direction DR2).

The partition wall PW may further have a non-light-emitting partition wall opening OPN-P overlapping the first opening OP1 of the pixel-defining film PDL in a plan view. The non-light-emitting partition wall opening OPN-P may include a first region A1a defined by a side surface of the first partition wall layer L1 and a second region A2a defined by a side surface of the second partition wall layer L2. The width of the first region A1a in one direction (for example, the first direction DR1 or the second direction DR2) may be larger than the width of the second region A2a in the one direction (for example, the first direction DR1 or the second direction DR2).

The display element layer DP-OLED may further include a first dummy pattern D1 and a second dummy pattern D2. The first dummy pattern D1 may include the same material as a material of the first light-emitting pattern EP1, and may be provided through the same process as a manufacturing process of the first light-emitting pattern EP1. A portion of the first dummy pattern D1 may be disposed in the first opening OP1 or the non-light-emitting partition wall opening OPN-P, and another portion of the first dummy pattern D1 may be disposed on the partition wall PW between the first partition wall opening OP1-P and the non-light-emitting partition wall opening OPN-P.

The second dummy pattern D2 may include the same material as a material of the first cathode CE1, and may be provided through the same process as a manufacturing process of the first cathode CE1. The second dummy pattern D2 may be disposed on the first dummy pattern D1. That is, a portion of the second dummy pattern D2 may be disposed in the first opening OP1 or the non-light-emitting partition wall opening OPN-P, and another portion of the second dummy pattern D2 may be disposed on the partition wall PW between the first partition wall opening OP1-P and the non-light-emitting partition wall opening OPN-P.

The thin-film encapsulation layer TFE may include inorganic lower encapsulation patterns LIL1, LIL2, and LIL3, an organic encapsulation film OL, and an inorganic upper encapsulation film UIL.

The inorganic lower encapsulation patterns LIL1, LIL2, and LIL3 may include a first inorganic lower encapsulation pattern LIL1 that covers the first light-emitting element ED1 and the second dummy pattern D2, a second inorganic lower encapsulation pattern LIL2 that covers the second light-emitting element ED2, and a third inorganic lower encapsulation pattern LIL3 that covers the third light-emitting element ED3.

The first inorganic lower encapsulation pattern LIL1 may overlap the first light-emitting opening OP1-E and the first opening OP1 in a plan view. A portion of the first inorganic lower encapsulation pattern LIL1 may be disposed in the first partition wall opening OP1-P and the non-light-emitting partition wall opening OPN-P, and another portion of the first inorganic lower encapsulation pattern LIL1 may be disposed on the partition wall PW. The second inorganic lower encapsulation pattern LIL2 may overlap the second light-emitting opening OP1-E in a plan view. A portion of the second inorganic lower encapsulation pattern LIL2 may be disposed in the second partition wall opening OP2-P, and another portion of the second inorganic lower encapsulation pattern LIL2 may be disposed on the partition wall PW. The third inorganic lower encapsulation pattern LIL3 may overlap the third light-emitting opening OP3-E in a plan view. A portion of the third inorganic lower encapsulation pattern LIL3 may be disposed in the third partition wall opening OP3-P, and another portion of the third inorganic lower encapsulation pattern LIL3 may be disposed on the partition wall PW. The first to third inorganic lower encapsulation patterns LIL1, LIL2, and LIL3 may be provided in patterns that are spaced apart from each other.

The organic encapsulation film OL may cover the inorganic lower encapsulation patterns LIL1, LIL2, and LIL3. The inorganic upper encapsulation film UIL may be disposed on the organic encapsulation film OL.

In an embodiment, after the second and/or third light-emitting elements ED2 and/or ED3 are formed, the first light-emitting element ED1 may be formed. In a washing process of the formation process of the second and/or third light-emitting elements ED2 and/or ED3, the pixel-defining film PDL may absorb moisture, and the moisture remaining on the pixel-defining film PDL may cause reliability issues on the display panel DP. According to an embodiment of the invention, the moisture remaining on the pixel-defining film PDL may be easily released through the first opening OP1 of the pixel-defining film PDL. As a result, defects of pixel in a display panel DP (dark spots, pixel shrinkage, etc.) may be reduced or eliminated.

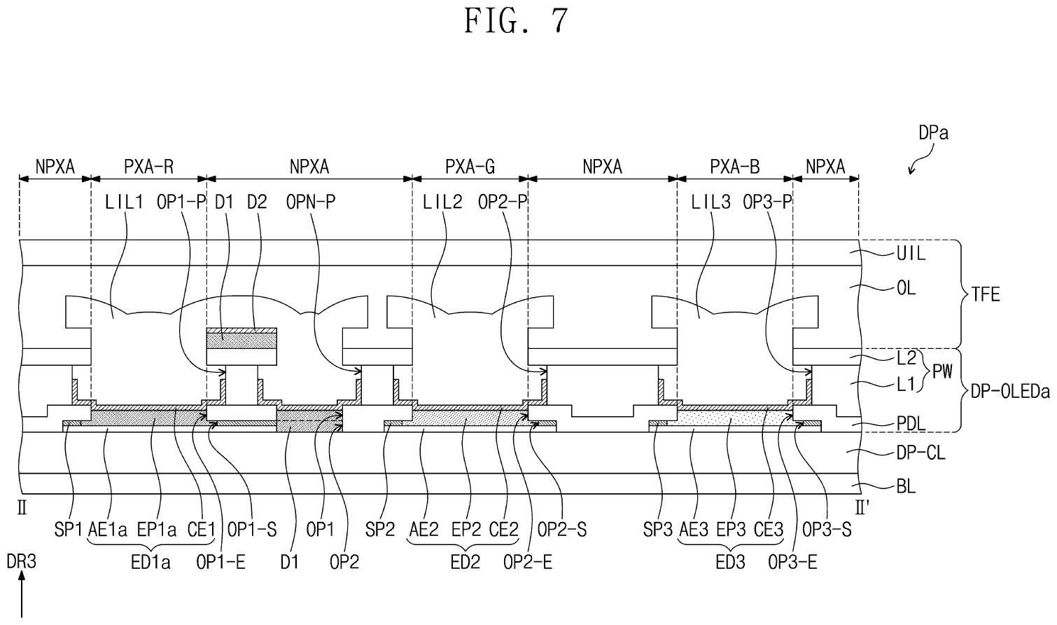

FIG. 7 is a cross-sectional view taken along line II-II′ of FIG. 4 according to another embodiment. In description with reference to FIG. 7, same/similar components as those described with reference to FIG. 6 are denoted as the same/similar reference symbols or numerals, and duplicate description thereof is omitted.

Referring to FIG. 7, a display panel DPa may include a base layer BL, a circuit element layer DP-CL, a display element layer DP-OLEDa, and a thin-film encapsulation layer TFE. The display element layer DP-OLEDa may include light-emitting elements ED1a, ED2, and ED3, sacrificial patterns SP1, SP2, and SP3, a pixel-defining film PDL, and a partition wall PW.

The light-emitting elements ED1a, ED2, and ED3 may include a first light-emitting element ED1a, a second light-emitting element ED2, and a third light-emitting element ED3 which emit different colors. The first light-emitting element ED1a may include a first anode AE1a, a first light-emitting pattern EP1, and a first cathode CE1. The first anode AE1a of the first light-emitting element ED1a may be disposed overlapping a first light-emitting region PXA-R and a non-light-emitting region NPXA.

The pixel-defining film PDL of the display element layer DP-OLEDa may have a first opening OP1. In the embodiment of FIG. 7, the display element layer DP-OLEDa may further have a second opening OP2. The second opening OP2 may be formed by a portion of the first anode AE1a and/or a first sacrificial pattern SP1, extending to the non-light-emitting region NPXA, being removed. The second opening OP2 may overlap the first opening OP1 and a non-light-emitting partition wall opening OPN-P in a plan view. The second opening OP2 may be provided adjacent to a first light-emitting region PXA-R, together with the first opening OP1. In an embodiment, the first light-emitting region PXA-R may be a light-emitting region corresponding to the last light-emitting element to be formed.

The display element layer DP-OLEDa may further include a first dummy pattern D1 and a second dummy pattern D2. The first dummy pattern D1 may include the same material as a material of the first light-emitting pattern EP1, and may be provided through the same process as a manufacturing process of the first light-emitting pattern EP1. In the embodiment of FIG. 7, a portion of the first dummy pattern D1 may be disposed in the first and second openings OP1 and OP2, and another portion of the first dummy pattern may be disposed on the partition wall PW between the first partition wall opening OP1-P and the non-light-emitting partition wall opening OPN-P.

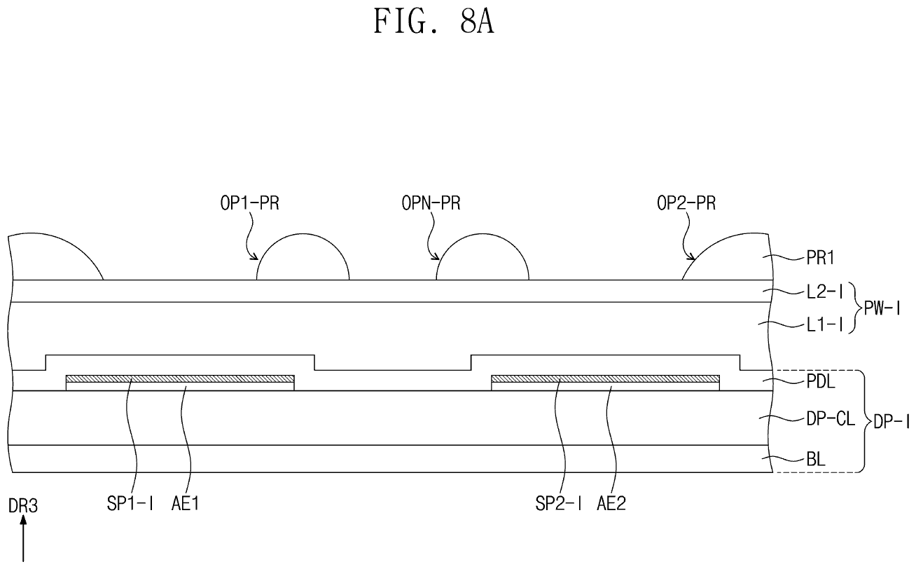

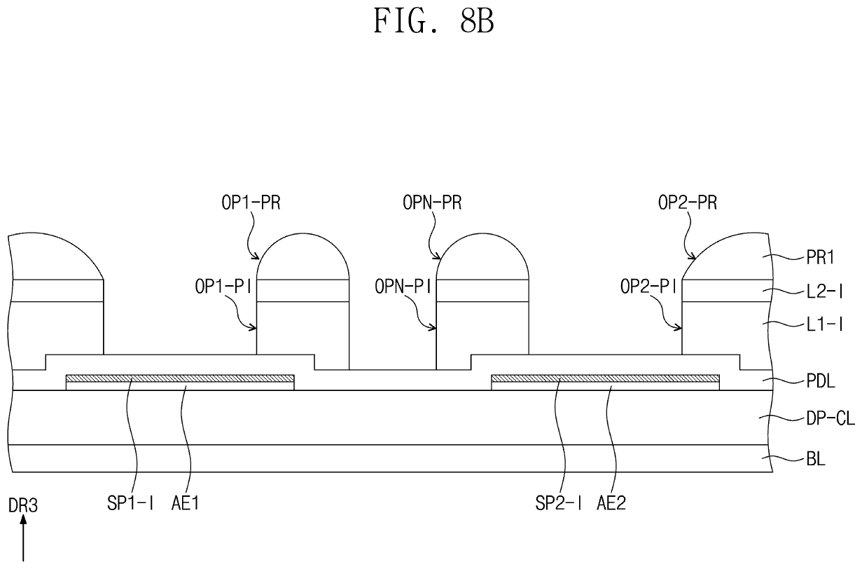

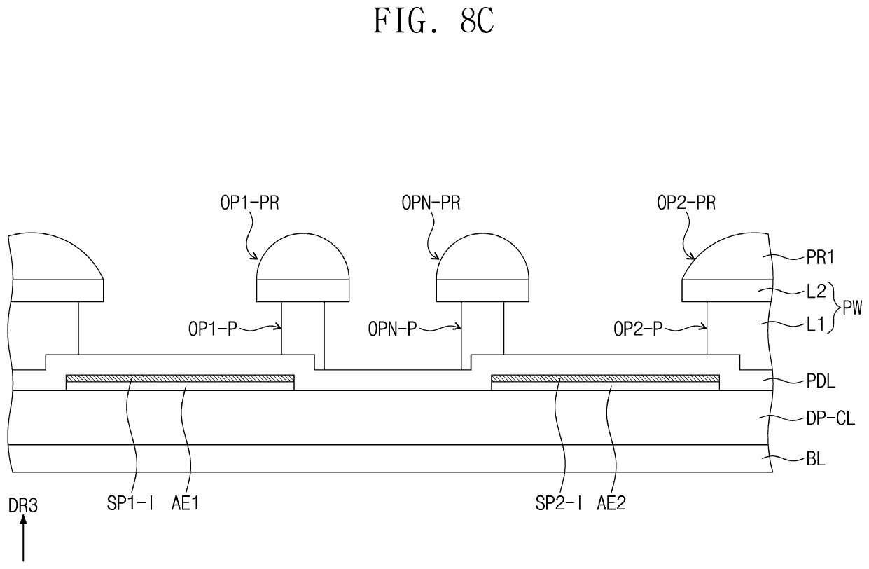

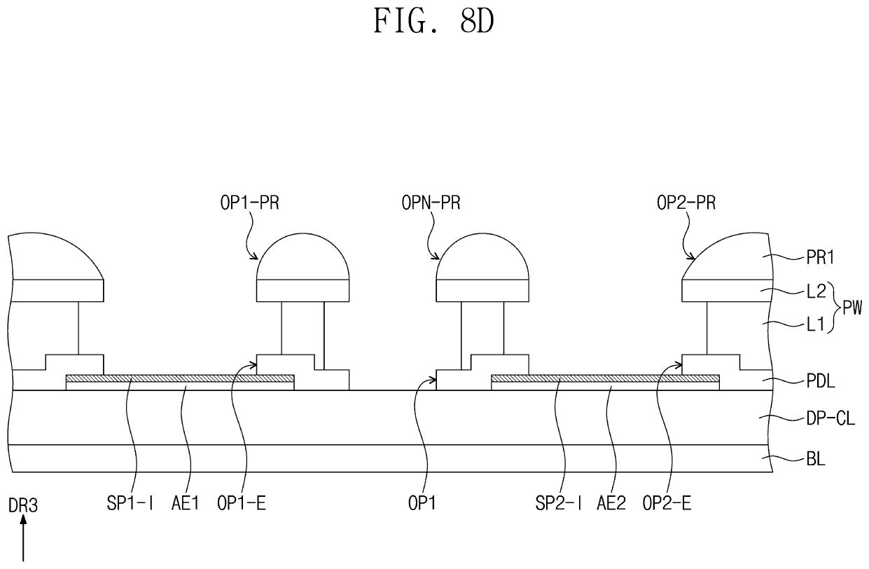

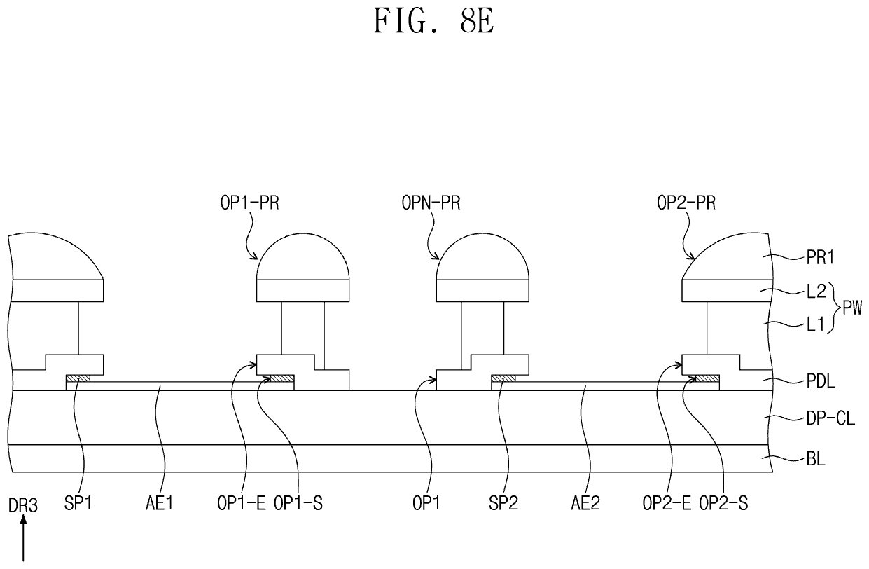

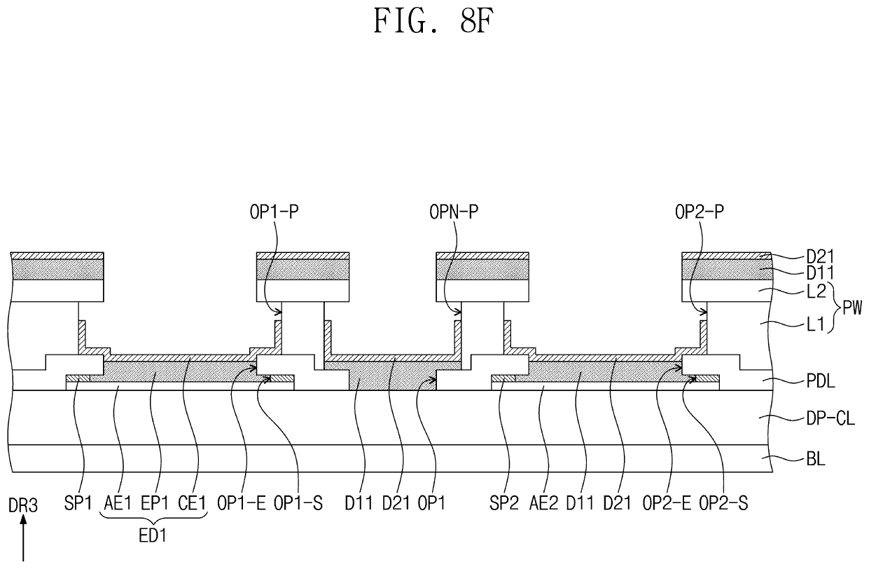

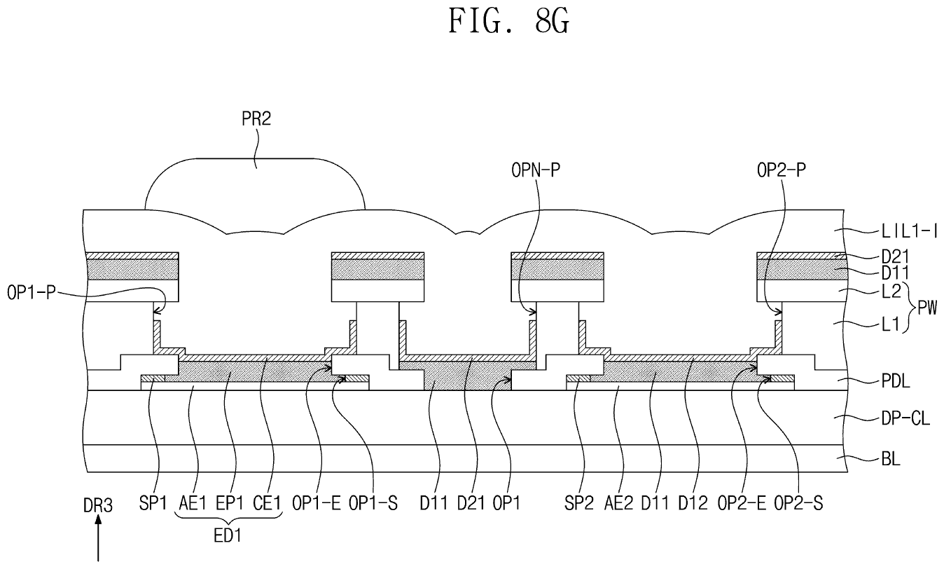

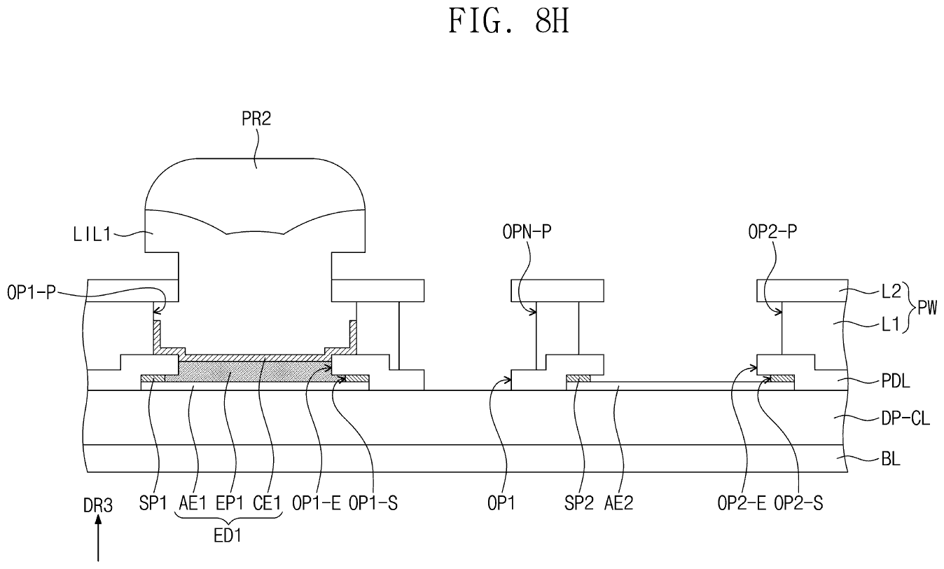

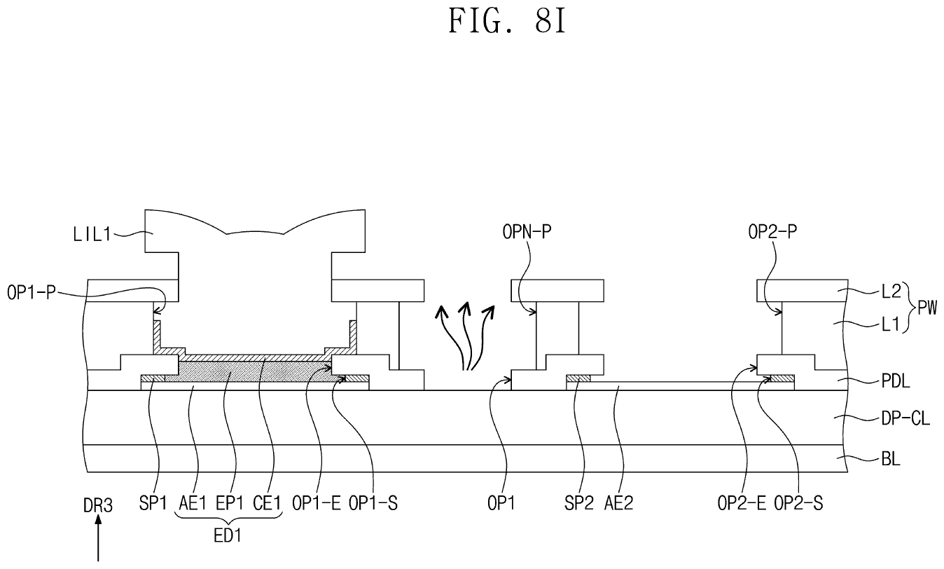

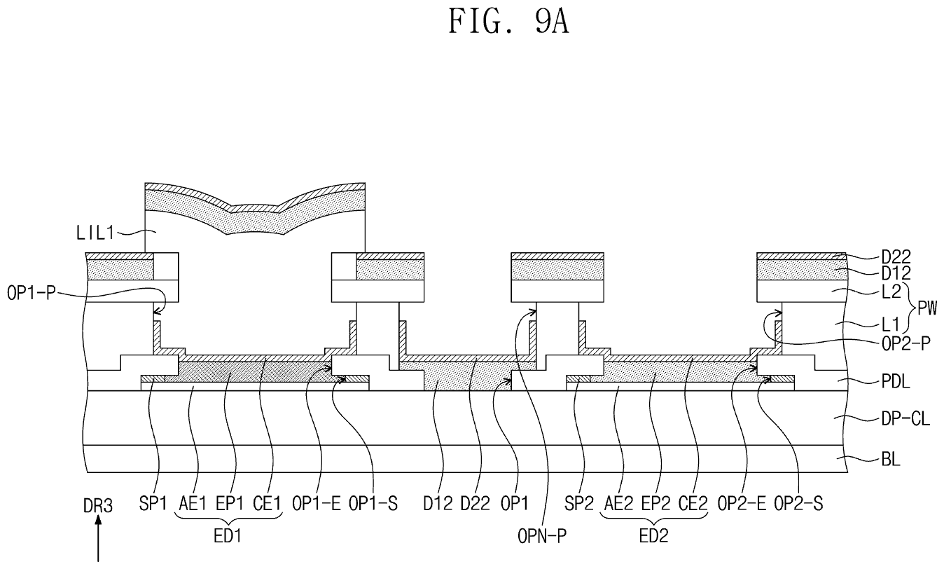

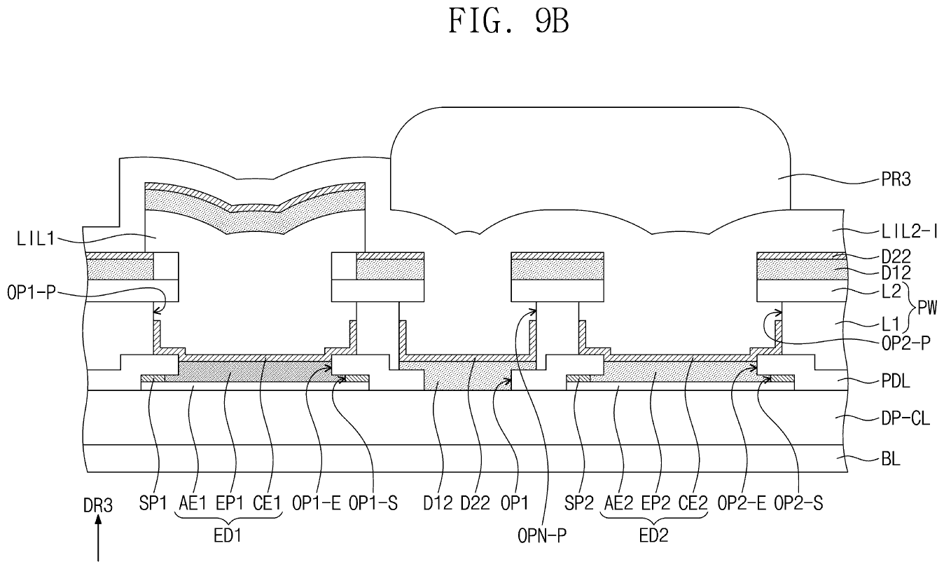

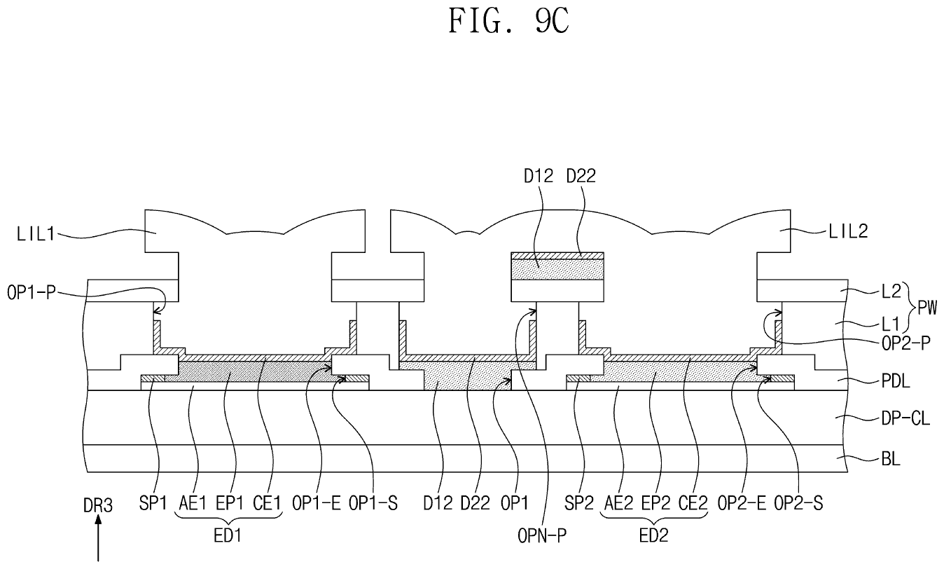

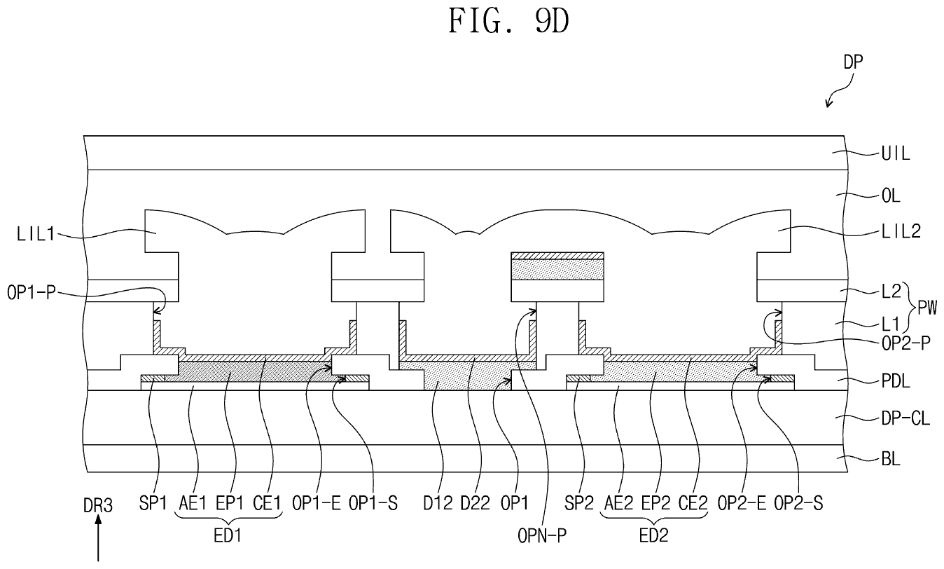

FIGS. 8A to 8I are cross-sectional views illustrating some steps of a manufacturing method for a display panel according to an embodiment of the invention. FIGS. 9A to 9D are cross-sectional views illustrating some steps of a manufacturing method for a display panel according to an embodiment of the invention. In description with reference to FIGS. 8A to 8I and FIGS. 9A to 9D, same/similar components as those described with reference to FIGS. 1 to 6 will be denoted as the same/similar reference numerals or symbols, and duplicate description thereof will be omitted.

A manufacturing method for a display panel according to an embodiment of the invention may include providing a preliminary display panel including a base layer, first and second anodes disposed on the base layer, and a pixel-defining film covering the first and second anodes, forming a preliminary partition wall on the preliminary display panel, etching the preliminary partition wall to form a partition wall having first and second partition wall openings overlapping the first and second anodes in a plan view, respectively, and a non-light-emitting partition wall opening between the first and second partition wall openings, etching the pixel-defining film to form first and second light-emitting openings overlapping the first and second partition wall openings in a plan view, respectively, and a first opening overlapping the non-light-emitting partition wall opening in a plan view, and forming a first light-emitting pattern and a first cathode in the first light-emitting opening and the first partition wall opening.

Hereinafter, through FIGS. 8A to 8I, forming a first light-emitting element ED1 and a first inorganic lower encapsulation pattern LIL1 that covers the first light-emitting element ED1 is described, and through FIGS. 9A to 9D, forming a second light-emitting element ED2 and a second inorganic lower encapsulation pattern LIL2 that covers the second light-emitting element ED2 is described. A display panel DP formed through FIGS. 8A to 8I and FIGS. 9A to 9D may correspond to a portion of the display panel DP of FIG. 6.

Referring to FIG. 8A, the manufacturing method for the display panel according to an embodiment of the invention may include providing a preliminary display panel DP-I. The preliminary display panel DP-I provided in this embodiment may include a base layer BL, a circuit element layer DP-CL, first and second anodes AE1 and AE2, first and second sacrificial layers SP1-I and SP2-I, and a pixel-defining film PDL.

The circuit element layer DP-CL may be formed through a general manufacturing process for a circuit element in which an insulation layer, a semiconductor layer, and a conductive layer are formed by coating, deposition, etc., and the insulation layer, the semiconductor layer, and the conductive layer are selectively patterned by a photolithography and etching processes to form a semiconductor pattern, a conductive pattern, a signal line, and the like.

The first anode AE1 and the first sacrificial layer SP1-I may be formed through the same patterning process, and the second anode AE2 and the second sacrificial layer SP2-I may be formed through the same patterning process. The pixel-defining film PDL may be disposed on the base layer BL. The pixel-defining film PDL may cover all of the first and second anodes AE1 and AE2 and the first and second sacrificial layers SP1-I and SP2-I.

The manufacturing method for the display panel according to an embodiment of the invention may include forming a preliminary partition wall PW-I on the preliminary display panel DP-I. The preliminary partition wall PW-I may include a first preliminary partition wall layer L1-I and a second preliminary partition wall layer L2-I. The first preliminary partition wall layer L1-I and the second preliminary partition wall layer L2-I may be formed through a deposition process of a conductive material. According to an embodiment of the invention, the first preliminary partition wall layer L1-I may include aluminum (Al), the second preliminary partition wall layer L2-I may include titanium (Ti), but the materials of the first preliminary partition wall layer L1-I and the second preliminary partition wall layer L2-I are not limited thereto. For example, the first preliminary partition wall layer L1-I and the second preliminary partition wall layer L2-I may include metal, transparent conductive oxide (TCO), or a combination thereof. The metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Thereafter, the manufacturing method for the display panel according to an embodiment of the invention may include forming a first photoresist layer PR1 on the preliminary partition wall PW-I. A preliminary photoresist layer may be formed on the preliminary partition wall PW-I, and then the preliminary photoresist layer may be patterned using a photo mask to form the first photoresist layer PR1. Through the patterning process, a first photo opening OP1-PR, a second photo opening OP2-PR, and a non-light-emitting photo opening OPN-PR may be formed in the first photoresist layer PR1. The first photo opening OP1-PR may overlap the first anode AE1, and the second photo opening OP2-PR may overlap the second anode AE2. The non-light-emitting photo opening OPN-PR may not overlap the first and second anodes AE1 and AE2 in a plan view.

Thereafter, referring to FIGS. 8B and 8C, the manufacturing method for the display panel according to an embodiment of the invention may include etching the preliminary partition wall PW-I (see FIG. 8A) to form a partition wall PW having first and second partition wall openings OP1-P and OP2-P and a non-light-emitting partition wall opening OPN-PR. The forming of the partition wall PW may include first etching and second etching.

First of all, as illustrated in FIG. 8B, the first etching of the first preliminary partition wall layer L1-I and the second preliminary partition wall layer L2-I may be performed by dry etching of the first preliminary partition wall layer L1-I and the second preliminary partition wall layer L2-I using the first photoresist layer PR1 as a mask. A portion of the preliminary partition wall PW-I not overlapping the first photoresist layer PR1 may be etched and removed. For example, on portions removed of the preliminary partition wall PW-I overlapping the first photo opening OP1-PR, the second photo opening OP2-PR, and the non-light-emitting photo opening OPN-PR, the first preliminary partition wall opening OP1-PI, the second preliminary partition wall opening OP2-PI, and the preliminary non-light-emitting partition wall opening OPN-PI in a plan view may be formed.

In this embodiment, the first dry-etching process may be performed in an etching condition where etch selectivity between the first preliminary partition wall layer L1-I and the second preliminary partition wall layer L2-I is substantially the same. Accordingly, an inner-side surface of the first preliminary partition wall layer L1-I and an inner-side surface of the second preliminary partition wall layer L2-I defining the first preliminary partition wall opening OP1-PI may be substantially aligned.

Thereafter, as illustrated in FIG. 8C, the second etching of the first preliminary partition wall layer L1-I (see FIG. 8B) may be performed by wet etching of the first preliminary partition wall layer L1-I using the first photoresist layer PR1 as a mask. Accordingly, portions of the first preliminary partition wall layer L1-I may be etched, so that the first partition wall opening OP1-P, the second partition wall opening OP2-P, and the non-light-emitting partition wall opening OPN-P may be formed. The first partition wall opening OP1-P may be defined overlapping the first anode AE1 in a plan view, the second partition wall opening OP2-P may be defined overlapping the second anode AE2, and the non-light-emitting partition wall opening OPN-P may not overlap the first and second anodes AE1 and AE2 in a plan view.

According to an embodiment of the invention, the second wet-etching process may be performed in a condition where etch selectivity between the first preliminary partition wall layer L1-I and the second preliminary partition wall layer L2-I (see FIG. 8B) is large. Accordingly, an inner side surface of the partition wall PW, defining the partition wall openings OP1-P, OP2-P, and OPN-P, may have an undercut shape in cross section. In particular, since an etch rate of the first preliminary partition wall layer L1-I is larger than an etch rate of the second preliminary partition wall layer L2-I for an etching solution, the first preliminary partition wall layer L1-I may be mainly etched. Accordingly, a first inner-side surface of the first partition wall layer L1 may be formed to be more recessed inward than a second inner-side surface of the second partition wall layer L2. A tip portion may be formed on the partition wall PW by a portion of the second partition wall layer L2 that is more protruding than the first partition wall layer L1.

The partition wall openings OP1-P and OP2-P may each include the first region A1 (see FIG. 6) defined by a side surface of the first partition wall layer L1, and the second region A2 (see FIG. 6) defined by a side surface of the second partition wall layer L2. The width of the first region A1 in one direction (for example, the first direction DR1 (see FIG. 4) or the second direction DR2 (see FIG. 4)) may be larger than the width of the second region A2 in the one direction (for example, the first direction DR1 or the second direction DR2).

The non-light-emitting partition wall opening OPN-P may include the first region A1a (see FIG. 6) defined by a side surface of the first partition wall layer L1 and the second region A2a (see FIG. 6) defined by a side surface of the second partition wall layer L2. The width of the first region A1a in one direction (for example, the first direction DR1 or the second direction DR2) may be larger than the width of the second region A2a in the one direction (for example, the first direction DR1 or the second direction DR2).

Thereafter, referring to FIG. 8D, the manufacturing method for the display panel according to an embodiment of the invention may include etching the pixel-defining film PDL to form first and second light-emitting openings OP1-E and OP2-E overlapping the first and second partition wall openings OP1-P and OP2-P, and a first opening OP1 overlapping the non-light-emitting partition wall opening OPN-P in a plan view.

The etching of the pixel-defining film PDL may be performed by dry etching of the pixel-defining film PDL using the first photoresist layer PR1 and the partition wall PW (for example, the second partition wall layer L2) as a mask. A portion of the pixel-defining film PDL not overlapping the first photoresist layer PR1 and the partition wall PW in a plan view may be etched and removed. As a result, the first and second light-emitting openings OP1-E and OP2-E and the first opening OP1 may be formed in the pixel-defining film PDL.

Referring to FIG. 8E, the manufacturing method for the display panel according to an embodiment of the invention may include etching the first and second sacrificial layers SP1-I and SP2-I (see FIG. 8D) to form first and second sacrificial patterns SP1 and SP2 having first and second sacrificial openings OP1-S and OP2-S overlapping the first and second light-emitting openings OP1-E and OP2-E in a plan view.

The etching of the first and second sacrificial layers SP1-I and SP2-I may be performed by wet etching of the first and second sacrificial layers SP1-I and SP2-I using the first photoresist layer PR1 and the partition wall PW (for example, the second partition wall layer L2) as a mask. Portions of the first and second sacrificial layers SP1-I and SP2-I not overlapping the first photoresist layer PR1 and the partition wall PW in a plan view may be etched and removed. As a result, the first and second sacrificial patterns SP1 and SP2 may be formed from the first and second sacrificial layers SP1-I and SP2-I. The first sacrificial opening OP1-S, overlapping the first light-emitting opening OP1-E, may be defined in the first sacrificial pattern SP1, and the second sacrificial opening OP2-S overlapping the second light-emitting opening OP2-E in a plan view may be defined in the second sacrificial pattern SP2.

The etching process of the first and second sacrificial patterns SP1 and SP2 may be performed in a condition where etch selectivity between the first sacrificial pattern SP1 and the first anode AE1 and etch selectivity between the second sacrificial pattern SP2 and the second anode AE2 are large, and accordingly, it may be possible to prevent the first and second anodes AE1 and AE2 from being etched together. That is, by disposing the first and second sacrificial patterns SP1 and SP2, having higher etch rates than those of the first and second anodes AE1 and AE2, between the pixel-defining film PDL and the first and second anodes AE1 and AE2, it may be possible to prevent damage caused by the first and second anodes AE1 and AE2 being etched together during the etching process.

Thereafter, referring to FIG. 8F, the manufacturing method for the display panel according to an embodiment of the invention may include removing the first photoresist layer PR1 (see FIG. 8E) and then forming a first light-emitting pattern EP1 and a first cathode CE1 in the first light-emitting opening OP1-E and the first partition wall opening OP1-P.

The forming of the first light-emitting pattern EP1 may include a deposition process of a light-emitting layer. For example, the forming of the first light-emitting pattern EP1 may include performing thermal evaporation on the light-emitting layer. The light-emitting layer may be divided by the tip portion formed on the partition wall PW, and may thus be deposited inside the first and second light-emitting openings OP1-E and OP2-E, the first and second partition wall openings OP1-P and OP2-P, the first opening OP1, and the non-light-emitting partition wall opening OPN-P. In addition, a portion of the light-emitting layer may be deposited on the partition wall PW.

A portion of the deposited light-emitting layer formed in the first light-emitting opening OP1-E and the first partition wall opening OP1-P may form the first light-emitting pattern EP1. The light-emitting layer deposited inside the second light-emitting opening OP2-E, the second partition wall opening OP2-P, the first opening OP1, and the non-light-emitting partition wall opening OPN-P and the light-emitting layer formed on the partition wall PW may form a (1-1)-th dummy pattern D11. The first light-emitting pattern EP1 may be formed overlapping the first partition wall opening OP1-P on the first anode AE1, and the first light-emitting pattern EP1 may be formed by covering the first anode AE1.

The (1-1)-th dummy pattern D11 formed together in the forming of the first light-emitting pattern EP1 may include an organic material. For example, the (1-1)-th dummy pattern D11 may include the same material as a material of the first light-emitting pattern EP1. The (1-1)-th dummy pattern D11 may be formed simultaneously with the first light-emitting pattern EP1 through one process, and may be formed separately from the first light-emitting pattern EP1 by the undercut shape of the partition wall PW.

The forming of the first cathode CE1 may include a deposition process of a cathode layer. For example, the forming of the first cathode CE1 may include performing sputtering on the cathode layer. The cathode layer may be divided by the tip portion formed on the partition wall PW, and may thus be deposited inside the first and second partition wall openings OP1-P and OP2-P and the non-light-emitting partition wall opening OPN-P. In addition, a portion of the cathode layer may be deposited on the partition wall PW.

A portion of the deposited cathode layer formed in the first partition wall opening OP1-P may form the first cathode CE1. The cathode layer deposited inside the second partition wall opening OP2-P and the non-light-emitting partition wall opening OPN-P and the cathode layer formed on the partition wall PW may form a (2-1)-th dummy pattern D21. The (2-1)-th dummy pattern D21 may be formed on the (1-1)-th dummy pattern D11. The first cathode CE1 may be formed overlapping the first partition wall opening OP1-P on the first light-emitting pattern EP1, and the first cathode CE1 may be formed by covering the first light-emitting pattern EP1. In addition, the first cathode CE1 may be formed by being in contact with a side surface of the first partition wall layer L1 to extend along the side surface of the first partition wall layer L1.

The (2-1)-th dummy pattern D21, formed together in the forming of the first cathode CE1, may include a conductive material. For example, the (2-1)-th dummy pattern D21 may include the same material as a material of the first cathode CE1. The (2-1)-th dummy pattern D21 may be formed simultaneously with the first cathode CE1 through one process, and may be formed separately from the first cathode CE1 by the undercut shape of the partition wall PW.

The first anode AE1, the first light-emitting pattern EP1, and the first cathode CE1 may be stacked in sequence along a third direction DR3. The first anode AE1, the first light-emitting pattern EP1, and the first cathode CE1 may form a first light-emitting element ED1.

Referring to FIGS. 8G and 8H, the manufacturing method for the display panel according to an embodiment of the invention may include forming a first inorganic lower encapsulation pattern LIL1 which covers the first light-emitting element ED1.

First of all, referring to FIG. 8G, the forming of the first inorganic lower encapsulation pattern LIL1 (see FIG. 8H) may include depositing a first inorganic lower encapsulation layer LIL1-I that covers inside portions of the partition wall openings OP1-P, OP2-P, and OPN-P and an upper portion of the partition wall PW. The first inorganic lower encapsulation layer LIL1-I may be formed through a deposition process. In an embodiment, the first inorganic lower encapsulation layer LIL1-I may be formed through a chemical vapor deposition process (CVD). The first inorganic lower encapsulation layer LIL1-I may be formed to cover the first cathode CE1, the (2-1)-th dummy pattern D21, and the partition wall PW. A portion of the first inorganic lower encapsulation layer LIL1-I may fill the inside portions of the partition wall openings OP1-P, OP2-P, and OPN-P.

Thereafter, the manufacturing method for the display panel according to an embodiment of the invention may include forming a second photoresist layer PR2. In the forming of the second photoresist layer PR2, a preliminary photoresist layer may be formed, and then the preliminary photoresist layer may be patterned using a photo mask to form the second photoresist layer PR2. Through the patterning process, the second photoresist layer PR2 may be formed in a form of a pattern corresponding to the first light-emitting element ED1.

Referring to FIG. 8H, the forming of the first inorganic lower encapsulation pattern LIL1 may include removing a portion of the first inorganic lower encapsulation layer LIL1-I (see FIG. 8G) not overlapping the first light-emitting element ED1 in a plan view. The removing of the portion of the first inorganic lower encapsulation layer LIL1-I not overlapping the first light-emitting element ED1 in a plan view may be performed by dry etching the first inorganic lower encapsulation layer LIL1-I using the second photoresist layer PR2 as a mask. A portion of the first inorganic lower encapsulation layer LIL1-I not overlapping the second photoresist layer PR2 in a plan view may be removed, and a portion of the first inorganic lower encapsulation layer LIL1-I remaining not etched may form the first inorganic lower encapsulation pattern LIL1.

Thereafter, the manufacturing method for the display panel according to an embodiment of the invention may include removing the (1-1)-th dummy pattern D11 and the (2-1)-th dummy pattern D21. The (2-1)-th dummy pattern D21 may be removed by wet etching, and the (1-1)-th dummy pattern D11 may be removed using a stripper. Through the removal processes, the (1-1)-th dummy pattern D11 and the (2-1)-th dummy pattern D21 disposed in the non-light-emitting partition wall opening OPN-P and the second partition wall opening OP2-P may be removed, and the (1-1)-th dummy pattern D11 and the (2-1)-th dummy pattern D21 disposed on the partition wall PW may also be removed.

Thereafter, referring to FIG. 8I, the manufacturing method for the display panel according to an embodiment of the invention may include removing the second photoresist layer PR2 (see FIG. 8H) and then drying the non-light-emitting partition wall opening OPN-P and the first opening OP1. The drying of the non-light-emitting partition wall opening OPN-P and the first opening OP1 may be a process where heat (for example, about 100° C. or less) is provided to outer surfaces of the non-light-emitting partition wall opening OPN-P and the first opening OP1 to evaporate residual moisture. As a result of the process, moisture may not exist in the non-light-emitting partition wall opening OPN-P and the first opening OP1.

Referring to FIG. 9A, the manufacturing method for the display panel according to an embodiment of the invention may include forming a second light-emitting pattern EP2 and a second cathode CE2 in the second light-emitting opening OP2-E and the second partition wall opening OP2-P.

The forming of the second light-emitting pattern EP2 may be substantially the same as the forming of the first light-emitting pattern EP1 in FIG. 8F. The forming of the second light-emitting pattern EP2 may include a deposition process of a light-emitting layer. For example, the forming of the second light-emitting pattern EP2 may include performing thermal evaporation on the light-emitting layer. The light-emitting layer may be divided by the tip portion formed on the partition wall PW, and may thus be deposited inside the second light-emitting opening OP2-E, the second partition wall opening OP2-P, the first opening OP1, and the non-light-emitting partition wall opening OPN-P. In addition, a portion of the light-emitting layer may be deposited on the partition wall PW and the first inorganic lower encapsulation pattern LIL1.

A portion of the deposited light-emitting layer formed in the second light-emitting opening OP2-E and the second partition wall opening OP2-P may form the second light-emitting pattern EP2. The light-emitting layer deposited inside the first opening OP1 and the non-light-emitting partition wall opening OPN-P and the light-emitting layer formed on the partition wall PW and the first inorganic lower encapsulation pattern LIL1 may form a (2-1)-th dummy pattern D21. The second light-emitting pattern EP2 may be formed overlapping the second partition wall opening OP2-P on the second anode AE2 in a plan view, and the second light-emitting pattern EP2 may be formed by covering the second anode AE2.

The (2-1)-th dummy pattern D21 formed together in the forming of the second light-emitting pattern EP2 may include an organic material. For example, the (2-1)-th dummy pattern D21 may include the same material as a material of the second light-emitting pattern EP2. The (2-1)-th dummy pattern D21 may be formed simultaneously with the second light-emitting pattern EP2 through one process, and may be formed separately from the second light-emitting pattern EP2 by the undercut shape of the partition wall PW.

The forming of the second cathode CE2 may include a deposition process of a cathode layer. For example, the forming of the second cathode CE2 may include performing sputtering on the cathode layer. The cathode layer may be deposited inside the second partition wall opening OP2-P and the non-light-emitting partition wall opening OPN-P. In addition, a portion of the cathode layer may be deposited on the partition wall PW and the first inorganic lower encapsulation pattern LIL1.

A portion of the deposited cathode layer formed in the second partition wall opening OP2-P may form the second cathode CE2. The cathode layer deposited inside the non-light-emitting partition wall opening OPN-P and the cathode layer formed on the partition wall PW and the first inorganic lower encapsulation pattern LIL1 may form the (2-2)-th dummy pattern D22. The (2-2)-th dummy pattern D22 may be formed on the (2-1)-th dummy pattern D21. The second cathode CE2 may be formed overlapping the second partition wall opening OP2-P on the second light-emitting pattern EP2 in a plan view, and the second cathode CE2 may be formed by covering the second light-emitting pattern EP2. In addition, the second cathode CE2 may be formed by being in contact with a side surface of the first partition wall layer L1 to extend along the side surface of the first partition wall layer L1.

The (2-2)-th dummy pattern D22 formed together in the forming of the second cathode CE2 may include a conductive material. For example, the (2-2)-th dummy pattern D22 may include the same material as a material of the second cathode CE2. The (2-2)-th dummy pattern D22 may be formed simultaneously with the second cathode CE2 through one process, and may be formed separately from the second cathode CE2 by the undercut shape of the partition wall PW.

The second anode AE2, the second light-emitting pattern EP2, and the second cathode CE2 may be stacked in sequence along a third direction DR3. The second anode AE2, the second light-emitting pattern EP2, and the second cathode CE2 may form a second light-emitting element ED2.

Referring to FIGS. 9B and 9C, the manufacturing method for the display panel according to an embodiment of the invention may include forming a second inorganic lower encapsulation pattern LIL2 which covers the (2-2)-th dummy pattern D22 (or second dummy pattern) and the second light-emitting element ED2.

First of all, referring to FIG. 9B, the forming of the second inorganic lower encapsulation pattern LIL2 (see FIG. 9C) may include depositing a second inorganic lower encapsulation layer LIL2-I which covers inside portions of the non-light-emitting partition wall opening OPN-P and the second partition wall opening OP2-P and upper portions of the partition wall PW and the (2-2)-th dummy pattern D22. The second inorganic lower encapsulation layer LIL2-I may be formed through a deposition process. In an embodiment, the second inorganic lower encapsulation layer LIL2-I may be formed through a chemical vapor deposition process (CVD). The second inorganic lower encapsulation layer LIL2-I may be formed to cover the inside portions of the non-light-emitting partition wall opening OPN-P and the second partition wall opening OP2-P and the upper portions of the partition wall PW and the (2-2)-th dummy pattern D22. A portion of the second inorganic lower encapsulation layer LIL2-I may fill the inside portions of the non-light-emitting partition wall opening OPN-P and the second partition wall opening OP2-P.

Thereafter, the manufacturing method for the display panel according to an embodiment of the invention may include forming a third photoresist layer PR3. In the forming of the third photoresist layer PR3, a preliminary photoresist layer may be formed, and then the preliminary photoresist layer may be patterned using a photo mask to form the third photoresist layer PR3. Through the patterning process, the third photoresist layer PR3 may be formed in a form of a pattern corresponding to the second light-emitting element ED2 and the non-light-emitting partition wall opening OPN-P adjacent thereto.

Referring to FIG. 9C, the forming of the second inorganic lower encapsulation pattern LIL2 may include removing a portion of the second inorganic lower encapsulation layer LIL2-I (see FIG. 9B) not overlapping the second light-emitting element ED2 and the non-light-emitting partition wall opening OPN-P in a plan view. The removing of the portion of the second inorganic lower encapsulation layer LIL2-I may be performed by dry etching of the second inorganic lower encapsulation layer LIL2-I using the third photoresist layer PR3 as a mask. A portion of the second inorganic lower encapsulation layer LIL2-I not overlapping the third photoresist layer PR3 in a plan view may be removed, and a portion of the second inorganic lower encapsulation layer LIL2-I remaining not etched may form the second inorganic lower encapsulation pattern LIL2.

Thereafter, the manufacturing method for the display panel according to an embodiment of the invention may include removing portions of the (1-2)-th dummy pattern D12 and the (2-2)-th dummy pattern D22. The (2-2)-th dummy pattern D22 may be removed by wet etching, and the (1-2)-th dummy pattern D12 may be removed using a stripper. Through the removal processes, the (1-2)-th dummy pattern D12 and the (2-2)-th dummy pattern D22 disposed on the first inorganic lower encapsulation pattern LIL1, and the (1-2)-th dummy pattern D12 and the (2-2)-th dummy pattern D22 disposed on the partition wall PW may be removed. However, the (1-2)-th dummy pattern D12 and the (2-2)-th dummy pattern D22 disposed on the partition wall PW between the non-light-emitting partition wall opening OPN-P and the second partition wall opening OP2-P may be covered by the second inorganic lower encapsulation pattern LIL2 and may thus not be removed, and the (1-2)-th dummy pattern D12 and the (2-2)-th dummy pattern D22 disposed in the first opening OP1 and the non-light-emitting partition wall opening OPN-P may also be covered by the second inorganic lower encapsulation pattern LIL2 and may thus not be removed.

Thereafter, referring to FIG. 9D, the manufacturing method for the display panel according to an embodiment of the invention may include forming an organic encapsulation film OL that covers the first and second inorganic lower encapsulation patterns LIL1 and LIL2. The organic encapsulation film OL may be formed by being applied through inkjet, but an embodiment of the invention is not limited thereto. The organic encapsulation film OL may provide a planar upper surface.

In addition, the manufacturing method for the display panel according to an embodiment of the invention may include forming an inorganic upper encapsulation film UIL to complete a display panel DP. Thereafter, the inorganic upper encapsulation film UIL may be formed by depositing an inorganic material. Through this, the display panel DP including a base layer BL, a circuit element layer DP-CL, a display element layer DP-OLED, and a thin-film encapsulation layer TFE may be formed.

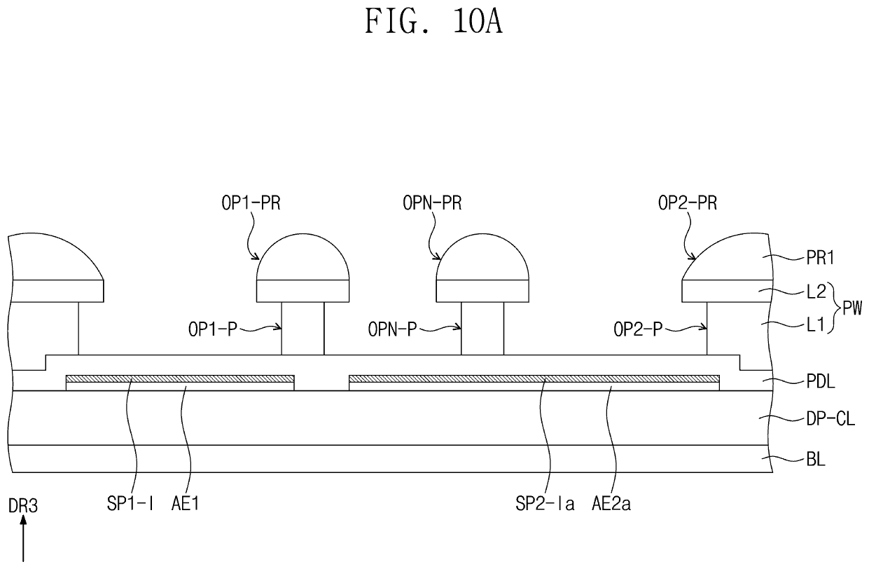

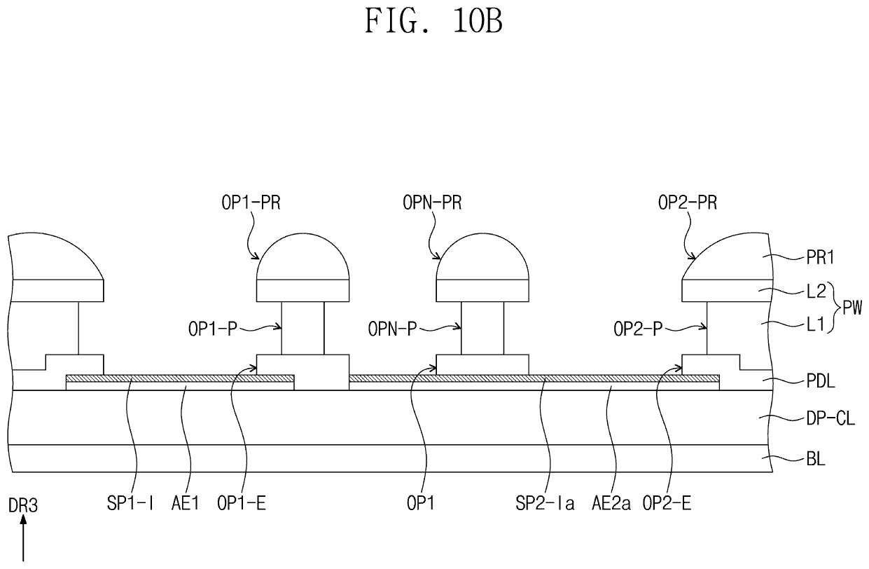

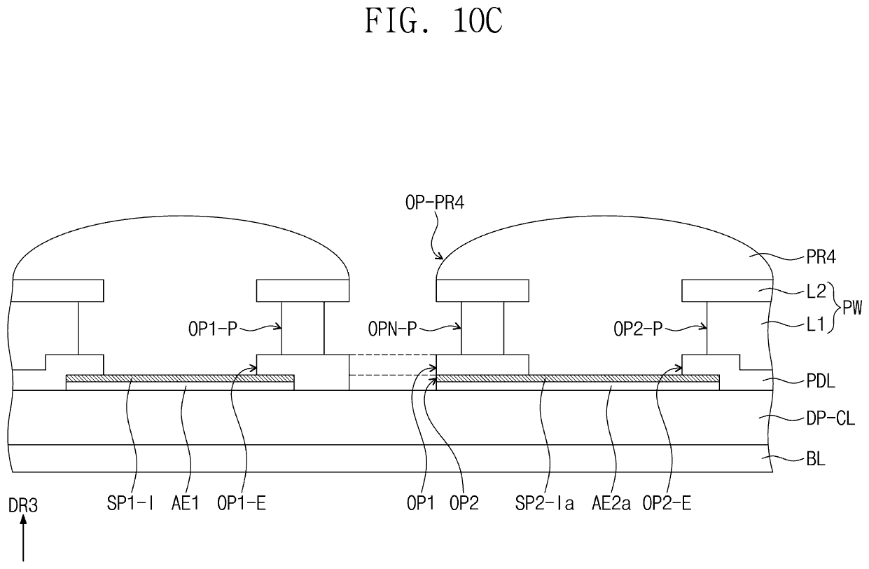

FIGS. 10A to 10C are cross-sectional views illustrating some steps of a manufacturing method for a display panel according to an embodiment of the invention. FIGS. 10A to 10C illustrate another embodiment corresponding to the processes of FIGS. 8C and 8D.

Referring to FIG. 10A, the preliminary display panel DP-I (see FIG. 8A) may include a base layer BL, a circuit element layer DP-CL, first and second anodes AE1 and AE2a, first and second sacrificial layers SP1-I and SP2-Ia, and a pixel-defining film PDL. In an embodiment, the second anode AE2a may be disposed overlapping a non-light-emitting partition wall opening OPN-P and a second partition wall opening OP2-P in a plan view. Furthermore, in an embodiment, the second sacrificial layer SP2-Ia may be disposed overlapping the non-light-emitting partition wall opening OPN-P and the second partition wall opening OP2-P in a plan view.

Thereafter, referring to FIG. 10B, the manufacturing method for the display panel according to an embodiment of the invention may include etching the pixel-defining film PDL to form first and second light-emitting openings OP1-E and OP2-E overlapping the first and second partition wall openings OP1-P and OP2-P and a first opening OP1 overlapping the non-light-emitting partition wall opening OPN-P in a plan view. A portion of the pixel-defining film PDL not overlapping a first photoresist layer PR1 and a partition wall PW in a plan view may be etched and removed. As a result, the first and second light-emitting openings OP1-E and OP2-E and the first opening OP1 may be formed in the pixel-defining film PDL. The first opening OP1 may expose a portion of the second anode AE2a and/or the second sacrificial layer SP2-Ia to the outside.

Referring to FIG. 10C, the manufacturing method for the display panel according to an embodiment of the invention may include forming a fourth photoresist layer PR4. In the forming of the fourth photoresist layer PR4, a preliminary photoresist layer may be formed, and then the preliminary photoresist layer may be patterned using a photo mask to form the fourth photoresist layer PR4. Through the patterning process, the fourth photoresist layer PR4 may be formed in a form of a pattern corresponding to the first partition wall opening OP1-P and the second partition wall opening OP2-P, and a fourth photo opening OP-PR4, defined in the fourth photoresist layer PR4, may overlap the non-light-emitting partition wall opening OPN-P in a plan view.

Thereafter, the manufacturing method for the display panel according to an embodiment of the invention may include etching the second anode AE2a overlapping the non-light-emitting partition wall opening OPN-P in a plan view to form a second opening OP2 overlapping the first opening OP1. In an embodiment, the second opening OP2 may be formed by etching the second anode AE2a and the second sacrificial layer SP2-Ia.

The etching of the second anode AE2a and/or the second sacrificial layer SP2-Ia may be performed by wet etching of the second anode AE2a and/or the second sacrificial layer SP2-Ia using the fourth photoresist layer PR4 and the partition wall PW (for example, the second partition wall layer L2) as a mask. A portion of the second anode AE2a and/or the second sacrificial layer SP2-Ia not overlapping the fourth photoresist layer PR4 and the partition wall PW in a plan view may be etched and removed. As a result, the second opening OP2 may be formed in the anode AE2a and/or the second sacrificial layer SP2-Ia.

According to what is described above, moisture remaining on the pixel-defining film may be easily released through a first opening of a pixel-defining film. As a result, defects of pixel in a display panel (dark spots, pixel shrinkage, etc.) may be reduced or eliminated.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention should not be limited to the contents described in the detailed description of the specification, but should be defined by the claims.

What is claimed is:

1. A display panel comprising:
a base layer; and
a display element layer, which is disposed on the base layer, and in which a light-emitting region and a non-light-emitting region adjacent to the light-emitting region are defined,
wherein the display element layer includes
a pixel-defining film disposed on the base layer, and defining a light-emitting opening overlapping the light-emitting region and a first opening overlapping the non-light-emitting region in a plan view,
a partition wall disposed on the pixel-defining film, and defining a partition wall opening overlapping the light-emitting opening and a non-light-emitting partition wall opening overlapping the first opening in the plan view, and
a light-emitting element disposed in the light-emitting opening or the partition wall opening, and having an anode, a light-emitting pattern, and a cathode in contact with the partition wall.

2. The display panel of claim 1, wherein the display element layer further comprises:
a first dummy pattern including a same material as a material of the light-emitting pattern; and
a second dummy pattern including a same material as a material of the cathode.

3. The display panel of claim 2, wherein the first dummy pattern and the second dummy pattern are disposed in the first opening or the non-light-emitting partition wall opening.

4. The display panel of claim 2, wherein the first dummy pattern and the second dummy pattern are disposed on the partition wall between the partition wall opening and the non-light-emitting partition wall opening.

5. The display panel of claim 2, further comprising an inorganic lower encapsulation pattern which covers the light-emitting element and the second dummy pattern.

6. The display panel of claim 5, wherein a portion of the inorganic lower encapsulation pattern is disposed in the partition wall opening and the non-light-emitting partition wall opening, and another portion of the inorganic lower encapsulation pattern is disposed on the partition wall.

7. The display panel of claim 1, wherein the anode is disposed overlapping the light-emitting region.

8. The display panel of claim 1, wherein the anode is disposed overlapping the light-emitting region and the non-light-emitting region.

9. The display panel of claim 8, wherein the display element layer further defines a second opening in a same layer with the anode and overlapping the first opening and the non-light-emitting partition wall opening in the plan view, and
the first dummy pattern is disposed in the first opening and the second opening.

10. The display panel of claim 1, wherein the partition wall comprises a first partition wall layer disposed on the pixel-defining film, and a second partition wall layer disposed on the first partition wall layer,
the partition wall opening comprises a first region defined by a side surface of the first partition wall layer and a second region defined by a side surface of the second partition wall layer,
a width of the first region in one direction is larger than a width of the second region in the one direction, and
the one direction is parallel to a major surface of the base layer.

11. The display panel of claim 10, wherein the non-light-emitting partition wall opening comprises a first region defined by a side surface of the first partition wall layer, and a second region defined by a side surface of the second partition wall layer, and a width of the first region in the one direction is larger than a width of the second region in the one direction.

12. A manufacturing method for a display panel, comprising:
providing a preliminary display panel including a base layer, first and second anodes disposed on the base layer, and a pixel-defining film covering the first and second anodes;
forming a preliminary partition wall on the preliminary display panel;
etching the preliminary partition wall to form a partition wall which defines first and second partition wall openings overlapping the first and second anodes in a plan view, and defines a non-light-emitting partition wall opening between the first and second partition wall openings;
etching the pixel-defining film to form first and second light-emitting openings overlapping the first and second partition wall openings and a first opening overlapping the non-light-emitting partition wall opening in the plan view; and
forming a first light-emitting pattern and a first cathode in the first light-emitting opening and the first partition wall opening.

13. The manufacturing method of claim 12, further comprising forming a first inorganic lower encapsulation pattern which covers a first light-emitting element.

14. The manufacturing method of claim 13, further comprising drying moisture which exists in the non-light-emitting partition wall opening and the first opening.

15. The manufacturing method of claim 14, further comprising:
forming a second light-emitting pattern and a second cathode in the second light-emitting opening and the second partition wall opening; and
forming a first dummy pattern and a second dummy pattern in the non-light-emitting partition wall opening and the first opening, and on the first inorganic lower encapsulation pattern and the partition wall.

16. The manufacturing method of claim 15, further comprising forming a second inorganic lower encapsulation pattern, which covers the second dummy pattern and a second light-emitting element.

17. The manufacturing method of claim 12, wherein the second anode is disposed overlapping the non-light-emitting partition wall opening and the second partition wall opening in the plan view.

18. The manufacturing method of claim 17, further comprising etching the second anode, which overlaps the non-light-emitting partition wall opening, to form a second opening overlapping the first opening in the plan view.

19. The manufacturing method of claim 12, wherein the partition wall, which defines the first and second partition wall openings and the non-light-emitting partition wall opening, comprises a first partition wall layer and a second partition wall layer,
each of the first and second partition wall openings and the non-light-emitting partition wall opening comprises a first region defined by a side surface of the first partition wall layer and a second region defined by a side surface of the second partition wall layer,
a width of the first region in one direction is larger than a width of the second region in the one direction and
the one direction is parallel to a major surface of the base layer.

20. An electronic device comprising a display panel, and
the display panel comprising:
a base layer; and
a display element layer, which is disposed on the base layer, and in which a light-emitting region and a non-light-emitting region adjacent to the light-emitting region are defined,
wherein the display element layer includes
a pixel-defining film disposed on the base layer, and defining a light-emitting opening overlapping the light-emitting region and a first opening overlapping the non-light-emitting region in a plan view,
a partition wall disposed on the pixel-defining film, and defining a partition wall opening overlapping the light-emitting opening and a non-light-emitting partition wall opening overlapping the first opening in the plan view, and
a light-emitting element disposed in the light-emitting opening or the partition wall opening, and having an anode, a light-emitting pattern, and a cathode in contact with the partition wall.
